(19) United States
(12) Patent Application Publication
(10) Pub. No.: US 2014/0076373 A1
(43) Pub. Date: Mar. 20, 2014

(54) FABRICATION OF NANOWIRE ARRAY COMPOSITES FOR THERMOELECTRIC POWER GENERATORS AND MICROCOOLERS

(71) Applicants: Timothy D. Sands, West Lafayette, IN (US); Kalapi G. Biswas, West Lafayette, IN (US)

(72) Inventors: Timothy D. Sands, West Lafayette, IN (US); Kalapi G. Biswas, West Lafayette, IN (US)

(21) Appl. No.: 13/607,717

(22) Filed: Sep. 8, 2012

Related U.S. Application Data
(62) Division of application No. 12/246,217, filed on Oct. 6, 2008, now abandoned.
(60) Provisional application No. 60/977,496, filed on Oct. 4, 2007.

(51) Int. Cl. H01L 35/34; H01L 35/26

(52) U.S. Cl. CPC H01L 35/34; H01L 35/26
USPC 136/236.1; 438/54; 205/153

(57) ABSTRACT

Methods for fabricating a nanowire array epoxy composite with high structural integrity and low effective thermal conductivity to achieve a power conversion efficiency goal of approximately 20% and power density of about 10⁴ W/m² with a maximum temperature below about 380° C. Further, a method includes fabricating a self-supporting thick 3-D interconnected nanowire array with high structural integrity and low effective thermal conductivity to achieve a power conversion efficiency goal of 20% and power density of about 10⁴ W/m² with a maximum temperature of about 700° C., the nanowire array having substantially only air between nanowires.

### RELATED APPLICATIONS

The present invention claims priority to co-pending U.S. patent application Ser. No. 12/246,217, filed on Oct. 6, 2008, which claimed priority to then co-pending U.S. Provisional Patent Application Ser. No. 60/977,496, filed on Oct. 4, 2007, the entirety of which are incorporated herein by reference.

This invention was made in part with support from Office of Naval Research with contract number N000140610641. The Government may have certain rights in the invention.

### TECHNICAL FIELD

The present invention generally relates to thermoelectric power generation and microcooling and particularly to nanowire structures.

### BACKGROUND

A significant amount of power consumed by the people of the world is converted to heat and released. For example, a significant amount of thermal energy is lost when lighting an incandescent light bulb. Although some researchers have investigated ways to reuse the lost thermal energy, currently, a significant amount of the electrical, fossil fuel, nuclear energy, and the like are lost to heat. Use of thermoelectric material is one way to recover the lost thermal energy. Thermoelectric devices positioned between hot and cold reservoirs can be used to generate electrical current. Conversely applying electrical current to thermoelectric devices can be used to transfer heat for microcooling applications.

The basis for thermoelectric power conversion is commonly referred to as the Seebeck effect, named after the discoverer of this phenomenon. The concept behind the Seebeck effect is shown in FIG. 1. For a small amount of thermal gradient at the junction of two materials, i.e., ΔT=T_{H}−T_{C}, a small voltage, ΔV is generated between the two materials, i.e., material A and material B, according to the formula

S=ΔV/ΔT,

wherein S is the Seebeck coefficient. In terms of the absolute value of the Seebeck coefficient, therefore, it is desirable to find material with higher Seebeck coefficients. In terms whether the Seebeck coefficient is a positive number or a negative number depends on whether the carriers are electrons or holes.

Besides the Seebeck coefficient, another efficiency measure for thermoelectric materials is the Figure of Merit (hereinafter, FOM”), commonly expressed as ZT. The formula for ZT is as follows:

ZT=(S²σ/κ)T,

wherein S is the Seebeck coefficient, σ is the electrical conductivity, κ is the thermal conductivity, and T is the temperature. In order to maximize the FOM, the thermoelectric material should have a large Seebeck coefficient, large electrical conductivity, and small thermal conductivity. Therefore, the selection of thermoelectric material requires balancing the need for low thermal conductivity and high electrical conductivity. Having a low thermal conductivity is necessary to minimize heat transfer from the hot reservoir to the cold reservoir, since such a heat transfer would eliminate or reduce the same thermal gradient that is producing the electrical power.

The transport of heat in thermoelectric materials is through both electrons and phonons. The thermal conductivity κ, also used in the FOM formula, is determined based on the following formula:

κ=κₑ+κₗ,

where κₑ is the electronic contribution to the heat transfer and κₗ is the lattice vibration contribution to the heat transfer. The electronic contribution to the thermal conductivity is expected to be roughly proportional to the electronic conductivity through the Lorenz factor (Wiedemann-Franz law) and hence, cannot be decreased further. However, by introducing phonon scattering, it is possible to reduce the thermal conductivity and thereby to decouple the electrical properties from the thermal properties.

Additionally, it is desirable to select a thermoelectric material structure having high yield, repeatability, and low cost to manufacture. Thin film thermoelectric structures initially showed promise. However, thin films suffer from slow growth rates and defect formation associated with lattice mismatch between constituent materials. Nanowires may grow to lengths greater than 10 μm by electrochemical methods. Nanowires also more readily accommodate lattice mismatch without introduction of defects such as misfit dislocations. In addition, the surfaces of nanowires scatter lattice vibrations, thereby reducing the thermal conductivity. Nanowires by themselves, however, do not have sufficient structural integrity and would therefore collapse. To address this issue, nanowires have been embedded in a matrix-like structure (also called a template) to provide the needed structural support. Porous anodic alumina (PAA), or otherwise commonly known anodic aluminum oxide (AAO), templates have been widely explored for nanowire array synthesis to allow for ordered, textured, high yield and low cost fabrication of thermoelectric materials and to enable high-performance direct thermal energy converters. However, it has been found that the alumina matrix with a thermal conductivity of 1.7 W/m-K can act as a thermal shunt. The thermal shunt phenomenon can substantially affect the efficacy of the thermoelectric operation.

Therefore, there is a need to reduce the thermal conductivity of the thermoelectric material and produce thermoelectric materials and designs that are structurally stable and have improved manufacturability.

### SUMMARY OF INVENTION

Embodiments of the present teachings are related to reducing thermal conductivity of nanowires used in thermoelectric power generators and microcoolers.

In one form, a method for making a nanowire structure for use in a thermoelectric device is disclosed. The method comprises electrodepositing nanowires into a template creating a nanowire array, whereby the template provides structural support for the nanowire array; removing at least a part of the template from the nanowire array; and infiltrating a composite into the nanowire array, whereby the composite provides structural support for the nanowire array.

In another form a nanowire structure for use in a thermoelectric device is disclosed. The nanowire structure comprises a nanowire array supported by a composite template, wherein the nanowire structure has a conversion efficiency of about 20% and a power density of about 10⁴ W/m² over an operational temperature range with a maximum temperature below about 380° C.

In yet another form a method for making a branched porous anodic alumina template for use in a thermoelectric device is disclosed. The method comprises cleaning an aluminum foil in a cleaning solution; electropolishing the cleaned aluminum foil; and anodic oxidizing the electropolished aluminum foil, whereby a branched porous anodic alumina template is grown having a plurality of vertical pores and a plurality of branched pores, wherein the growth rate of the branched porous anodic alumina template is at about 300 μm/hour.

In still yet another form, a nanowire structure for use in a thermoelectric device is disclosed. The nanowire structure comprises a compositionally modulated nanowire array.

### BRIEF DESCRIPTION OF DRAWINGS

The above-mentioned and other advantages of the present invention and the manner of obtaining them will become more apparent and the invention itself will be better understood by reference to the following description of the embodiments of the invention taken in conjunction with the accompanying drawings, wherein:

FIG. 1 is a schematic view of a generic thermoelectric power generator;

FIG. 2(a) is a plan view of a PAA template before nanowires are grown to the template;

FIG. 2(b) is a plan view Field Emission Scanning Electron Microscopy (FESEM) image of 200 nm diameter Bi₂Te₃ nanowire array in a PAA template;

FIG. 3(a) is an animation view of process-flow for polymer infiltration for growing nanowire in PAA template;

FIG. 3(b) is an animation view of process-flow for polymer infiltration for etching back the PAA template;

FIG. 3(c) is an animation view of process-flow for polymer infiltration for infiltrating SU-8;

FIG. 4(a) is a detailed animation view of process-flow for polymer infiltration showing nanowire growth in PAA template;

FIG. 4(b) is a detailed animation view of process-flow for polymer infiltration showing overgrowth of nanowire in PAA template;

FIG. 4(c) is a detailed animation view of process-flow for polymer infiltration showing planarization of nanowire in PAA template;

FIG. 4(d) is a detailed animation view of process-flow for polymer infiltration showing etchback operation of in PAA template;

FIG. 4(e) is a detailed animation view of process-flow for polymer infiltration showing infiltration of SU-8 around the nanowire array;

FIG. 5(a) is a plan view of commercially available PAA templates (Anodic) have with an average pore diameter of 80 nm;

FIG. 5(b) is a plan view of commercially available PAA templates (Anodic) have with an average pore diameter of 80 nm;

FIG. 6(a) is a plan view FESEM image of Bi₂Te₃ nanowire array composite exhibiting a dense nanowire array with 75% volume fraction;

FIG. 6(b) is a cross-sectional view FESEM image of Bi₂Te₃ nanowire array composite revealing a high aspect ratio (200:1);

FIG. 7(a) is a plan view of a nanowire array of Bi₂Te₃ in a PAA template;

FIG. 7(b) is a plan view of a nanowire array of Bi₂Te₃ in a SU-8 composite infiltrated template;

FIG. 8(a) is a cross-sectional view of a fractured nanowire array in an epoxy composite wherein the nanowires are completely embedded in the epoxy matrix;

FIG. 8(b) is a magnified view of a cross-sectional view of a fractured nanowire array in an epoxy composite wherein the nanowires are completely embedded in the wherein the magnified view shows cleavage plane in nanowire corresponding to weak van der Waals forces in Te—Te planes in Bi₂Te₃ crystal structure;

FIG. 9 is a crystal structure representation of Bi₂Te₃ showing quintet of Bi atoms and Te atoms in the Bi₂Te₃ crystal structure with the dashed lines indicating van der Waals bonding between the Te²—Te² atomic planes;

FIG. 10 is X-ray diffraction (XRD) patterns from deposited Bi₂Te₃ nanowire array and Bi₂Te₃ thin film revealing that all reflections from Bi₂Te₃ powder diffraction pattern appear in the XRD scan of Bi₂Te₃ thin film, whereas only the 110 peak is dominant in the case of Bi₂Te₃ nanowire array;

FIG. 11 is a schematic showing a self-supported nanowire array with the template removed;

FIG. 12(a) is a plan view of a conventional PAA illustrating the hexagonal arrangement of pores, outer crystalline oxide layer near the Al—Al₂O₃ interface (M/O) and an inner amorphous oxide layer adjacent to the Al₂O₃-electrolyte interface (O/E);

FIG. 12(b) is a cross-sectional view of a conventional PAA illustrating the pore size (Dₚ), spacing between the pores (Dᵢₙₜ), pore wall thickness (2T) and scalloped bottom (barrier layer) thickness (t_{barrier});

FIG. 13(a) is a typical electrical transient trends in the formation of porous anodic alumina (PAA) using a constant potential condition;

FIG. 13(b) is a typical electrical transient trends in the formation of porous anodic alumina (PAA) using a constant current condition;

FIG. 14(a) is a cross-sectional FESEM image of an interconnected branched porous template showing the total thickness of the template being in the order of 100 microns;

FIG. 14(b) is a magnified cross-sectional FESEM image of an interconnected branched porous template showing a representative region in the B-pAA template displaying the branched network, pore diameter of about 200 nm, and pore wall thickness of about 20 nm;

FIG. 14(c) is a cross-sectional FESEM image of an interconnected branched porous template showing a 3-D quasi-periodic network of pores throughout the template;

FIG. 14 (d) is a magnified cross-sectional FESEM image of an interconnected branched porous template showing a B-PAA/Al interface indicating vertical and inclined scallops (barrier layer) at the bottom of each pore (about 500 nm) and a higher degree of quasi-periodic scalloping effect throughout the interface (corresponding to a period of about 5).tm);

FIG. 15(a) is a plan view of a first magnification FESEM image of a B-pAA template showing the side facing the electrolyte during anodization indicating the preferential etching of the amorphous Al₂O₃ from the pore walls leaving behind crystalline Al₂O₃ fibers;

FIG. 15(b) is a plan view of a second magnification FESEM image of a B-PAA template showing the side facing the electrolyte during anodization indicating the preferential etching of the amorphous Al₂O₃ from the pore walls leaving behind crystalline Al₂O₃ fibers;

FIG. 15(c) is a plan view of a third magnification FESEM image of a B-PAA template showing the side facing the electrolyte during anodization indicating the preferential etching of the amorphous Al₂O₃ from the pore walls leaving behind crystalline Al₂O₃ fibers;

FIG. 16(a) is an electrical transient trends in the formation of a B-PAA using a constant potential condition revealing four stages of growth, Stage 1: incubation period of 360 sec and onset of barrier oxide formation, Stage II: vertical pore growth of primary pores at 380 sec, Stage IIa: secondary pore formation at 480 sec, and Stage III: pore growth stabilization at 660 sec;

FIG. 16(b) is an electrical transient trends in the formation of a B-PAA using a constant current condition revealing the four stages of growth of FIG. 16(a);

FIG. 17(a) is FESEM cross-sectional views at different magnifications of the anodization process showing stage II of FIG. 16(a) indicating pore initiation and growth of vertical pores;

FIG. 17(b) is FESEM cross-sectional views at different magnifications of the anodization process showing stage IIa of FIG. 16(a) indicating transition from primary vertical pore formation to secondary branched pore formation, further indicating the quasi-periodic selection of vertical pores on which the secondary pores originate;

FIG. 18(a) is a FESEM plan view image of the sample with Case 1 conditions: 160V, 1.1 A/cm², 0.4M and 4° C. after 10 sec anodization process (side S1 having a thickness about 6 μm, average Dₚ of about 150 nm and Dᵢₙₜ of about 300 nm);

FIG. 18(b) is a FESEM cross-sectional view image of the same condition as FIG. 18(a);

FIG. 19(a) is a FESEM plan view image of the sample with Case 1 conditions: 160V, 1.1 A/cm², 0.4M and 4° C. after 10 sec anodization process (side S1 having a thickness of about 15 μm, average Dₚ of about 170 nm and Dᵢₙₜ of about 280 nm);

FIG. 19(b) is a FESEM cross-sectional view image of the same condition as FIG. 19(a);

FIG. 20(a) is a FESEM plan view image of the sample with Case 1 conditions: 160V, 1.1 A/cm²,0.4M and 4° C. after 10 sec anodization process (side S1 having a thickness of about 15 μm, average Dₚ of about 170 nm and Dᵢₙₜ of about 280 nm);

FIG. 20(b) is a FESEM cross-sectional view image of the same condition as FIG. 20(a);

FIG. 21 is a cross-sectional FESEM image of B-PAA in 0.3 M phosphoric acid for a growth duration of 7 min under Case 2 conditions:160V, 1.1 A/cm², 0.3M and 4° C. (the initial layer comprising of vertical pores have been completely etched away by Al₂O₃ dissolution leading to a thickness of about 20 μm);

FIG. 22(a) show cross-sectional and plan FESEM views of B-PAA grown under Case 3 condition (160V, 1.1 A/cm², 0.4M and 90° C.) with anodization process stopped at 10 sec, indicating formation of vertical pores of thickness of about 3 μm and Dₚ of about 150 nm;

FIG. 22(b) show cross-sectional and plan FESEM views of B-PAA grown under Case 3 condition (160V, 1.1 A/cm², 0.4M and 90° C.) with anodization process stopped at) 30 sec: indicating vertical pores of about 15 μm and Dₚ of about 200 nm;

FIGS. 23(a) and 23(b) are plan and cross-sectional FESEM view of B-PAA using a current limited condition of 0.01 A (current density of about 4 mA/cm²), the anodization process was continued for 60 min, a vertical pore thickness of about 2.5 μm, average pore diameter Dₚ of about 55 nm, barrier layer thickness t_{barrier} of about 170 nm and interpore spacing Dᵢₙₜ of about 160 nm are indicated at the top surface and Dᵢₙₜ of about 400 nm indicated at the bottom layer;

FIG. 24(a) show cross-sectional and plan FESEM views of B-PAA grown under Case 5 condition with anodization process stopped at (a) 10 sec, indicating formation of vertical pores of thickness of about 5 μm, Dp of about 100 nm, and Dᵢₙₜ of about 260 nm;

FIG. 24(b) show cross-sectional and plan FESEM views of B-PAA grown under Case 5 for 30 sec, indicating about 10 μm vertical pores and about 5 μm branched pores, Dₚ of about 260 nm, Dᵢₙₜ of about 270 nm;

FIG. 24(c) show cross-sectional and plan FESEM views of B-PAA grown under Case 5 for 60 sec, indicating about 50 μm branched pores and Dₚ of about 260 nm;

FIG. 25 is a plot of strain energy density along the nanowire axis where the zero line is considered at the interface of the nanowire A and nanowire, whereby The strain energy density decreases exponentially away from the interface along the +ve and −ve z directions (nanowire axis);

FIG. 26 is a plot of cyclic voltammogram of Bi—Te—Se material system on Pt substrate (the reduction peaks occur at potentials of 40 mV and −60 mV respectively);

FIG. 27 shows in animation a multilayer nanowire with varying composition of Bi₂(Te,Se)₃; and

FIG. 28 shows an FESEM image of a compositionally modulated multilayer nanowire array, the layer contrast provides information about the segment lengths of 70 nm corresponding to the condition of 40 mV and 2 sec growth duration and 130 nm corresponding to the condition of −60 mV and 5 sec growth duration.

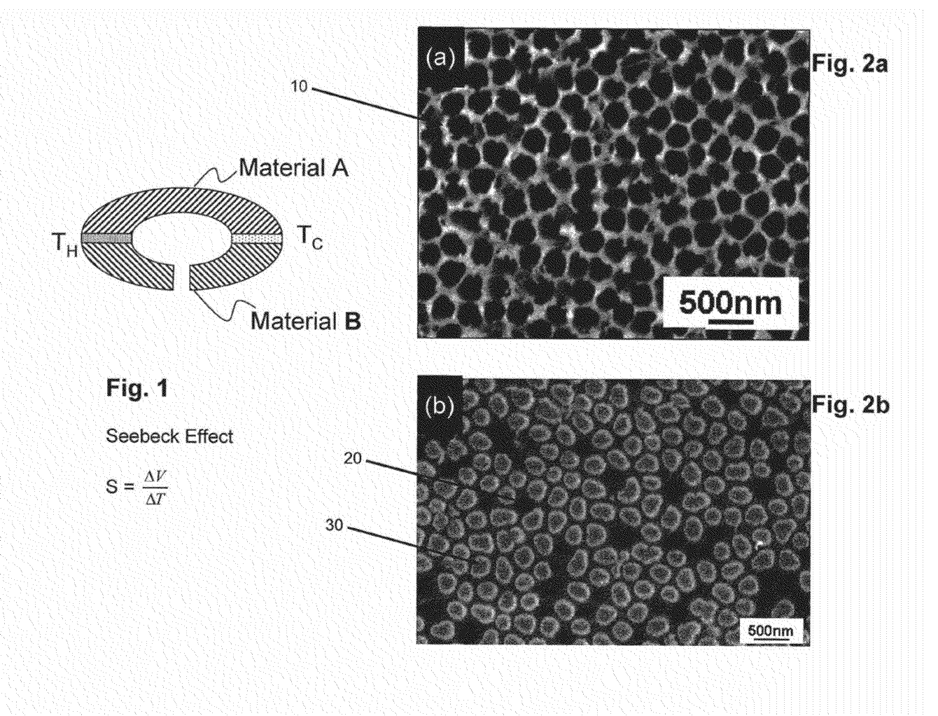

### DETAILED DESCRIPTION

The embodiments of the present invention described below are not intended to be exhaustive or to limit the invention to the precise forms disclosed in the following detailed description. Rather, the embodiments are chosen and described so that others skilled in the art may appreciate and understand the principles and practices of the present invention.

These teachings relate to reduction of thermal conductivity of nanowires. Nanowires that are grown substantially linearly require a supporting structure. Without the supporting structure nanowires can collapse. Templates (matrix-like structures), such as PAA templates, have been used to provide the structural support for nanowires. FIGS. 2a and 2b show Field Emission Scanning Electron Microscopy (FESEM) plan views of a PAA template before nanowires are grown (FIG. 2a) and after nanowires are grown (FIG. 2b). Referring to FIG. 2a, the honeycomb structure contains receiving ports 10 for growing nanowires. Referring to FIG. 2b, some of non-filled receiving ports 20 are shown while nanowires 30 which have been grown populate most of the receiving ports.

The PAA template has a thermal conductivity of 1.7 W/m-K. Therefore, the PAA can provide a parasitic thermal shunt and thereby limit the desired reduction of the thermal conductivity.

The current teachings provide four approaches to reduce or eliminate the parasitic thermal shunt because of the PAA template. In all four approaches, these teachings focus on nanostructured materials such as BhTe3. The first approach is related to replacing the PAA template with a lower thermal conductivity polymer. The second approach is to completely eliminate the template by fabricating a self supporting interconnected nanowire array. The third approach is to compositionally modulate two materials, such as Bi₂Te₃/Bi₂Se₃, as the nanowires are grown in the polymer-supported configuration. Finally the fourth approach is to compositionally modulate two materials, such as Bi₂Te₃/Bi₂Se₃, as the nanowires are grown in the self-supporting configuration.

The current teachings also apply to a class of materials based on PbTe (lead telluride) and its alloys. These materials work at higher temperatures, without degradation. Higher temperature gradients between the cold and hot reservoirs result in higher power generations. The techniques that are discussed in these teachings will apply to the class of materials based on PbTe.

Replacement of PAA with a Polymer Having a Low Thermal Conductivity

A process for fabricating a nanowire array infiltrated with an epoxy composite having a high structural integrity and yet a low effective thermal conductivity is provided. This process focuses on the low temperature thermoelectric range, e.g., below 200T. Textured Bi₂Te₃ nanowires were electrodeposited and grown into sacrificial PAA templates. The array was then infiltrated with an epoxy compound.

The decision of which polymer is suitable for replacing the PAA template is based on several criteria. These criteria are: (i) thermal conductivity, (ii) viscosity, (iii) wetting and adhesion, (iv) mechanical stability, (v) shrinkage and (vi) thermal reliability. Based on these criteria, several polymers were identified. These are (a) SU-8 epoxy resin having a thermal conductivity of about 0.2 W/m-K; (b) polyamic acid, having a thermal conductivity of about 0.17 W/m-K; (c) silicone, having a thermal conductivity of about 0.77 W/m-K; (d) polystyrene, having a thermal conductivity of about 0.13 W/m-K; and (e) polymethyl methacrylate (PMMA), having a thermal conductivity of about 0.17 W/m-K.

Although any of the above polymers may also be a suitable choice for replacing the PAA template, SU-8 resin was chosen as the polymer of choice. This decision was based on the fact that SU-8 is already widely used in the microelectronics industry for high aspect ratio and 3-D lithographic patterning, due to its photoresist qualities. It is also already widely accepted as a permanent and functional material in silicon-on-insulator technologies.

The SU-8 has a low thermal conductivity of about 0.2 W/m-K, which is an order of magnitude lower than PAA, which has a thermal conductivity of about 1.7 W/m-K. Another advantage of the SU-8 is its low viscosity of its precursor in a solvent, about 45 eSt. The suitable choice for replacing the PAA template must have a low viscosity to be able infiltrate between the nanowires. The PAA template wall separating the adjacent nanowires is about 50 nm in width. Meanwhile, the overall template thickness is about 40 μm. Therefore, the ratio of the overall template thickness to the distance separating the adjacent nanowires is about 800:1. Given the low viscosity of SU-8 epoxy resin, the SU-8 epoxy can fill the space around the nanowires, given such a high aspect ratio as described above, with minimal lateral flow. The structural integrity that is sought by adding the SU-8 epoxy is determined by the BhTe3 nanowire surface properties. SU-8 has a high degree of cross-linking and is known for its high chemical and mechanical stability after photo-thermal processing. In addition, it has a high degradation temperature (380° C.) and displays a low volume shrinkage upon cross-linking of about 7.5%. These properties made the SU-8 epoxy resin the material of choice for replacing the PAA template. However, as mentioned above other material, examples of which are provided above, may also be used with varying degrees of success in replacing the PAA template as a way to provide the necessary structural support needed for the nanowires.

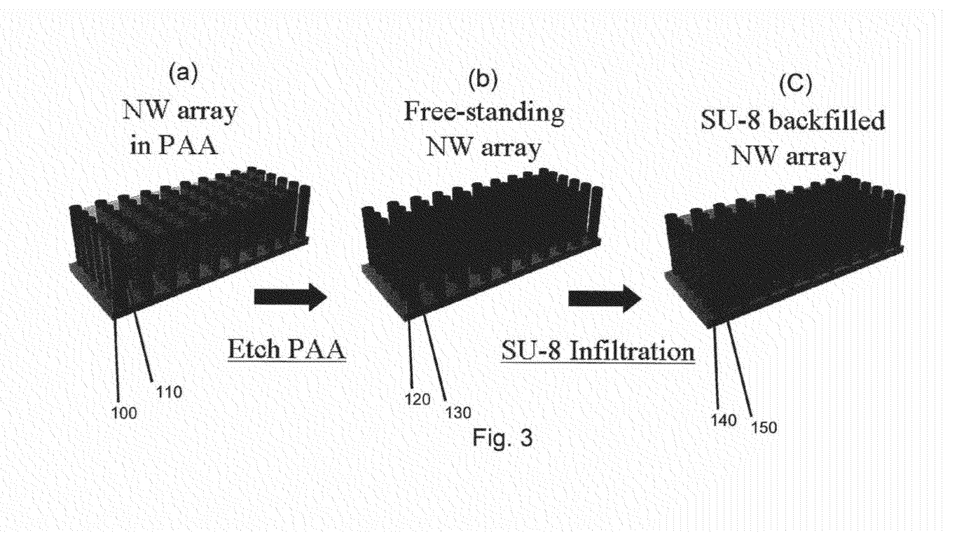

FIG. 3 shows animations of the process for removing the PAA template and replacing that with the SU-8 epoxy resin. FIG. 3a) shows in animation nanowires in a PAA template. Nanowires 100 are held in place with PAA template 110 between the nanowires. FIG. 3(b) shows in animation removal of the PAA template. Nanowires 120 are temporarily held without the PAA template. The reference numeral 130 indicates the removal of PAA. FIG. 3(c) shows in animation replacement of PAA with SU-8 as indicated by reference numeral 150 around nanowires 140.

For fabricating the nanowire array/SU-8 composite, the PAA template is removed by etching in a 3 wt % KOH solution for 24 hours. While the PAA is being etched, the free-standing Bi₂Te₃ nanowires may collapse due to capillary forces acting on nanowire sidewalls. In order to prevent the collapse of these free-standing Bi₂Te₃ nanowires, the nanowires are rinsed with de-ionized water (72 mNm−1). This rinsing procedure is followed by rinsing with a lower surface tension solvent, e.g., isopropanol (21.8 mNm-1). The result of these rinsing procedures is an array of 40-micron-thick self-supporting planarized BhTe3 nanowire. Next, the SU-8 epoxy resin is then spin-coated on the nanowire array at 2000 rpm to obtain a resin matrix thickness of 40 μm followed by UV processing at about 360 nm. SU-8 resin contains acid-labile groups and a photoacid generator, which on irradiation decomposes to generate a low concentration of catalyst acid. Subsequent heating of the polymer activates cross-linking and regenerates the acid catalyst. Solvent removal by soft baking contributes to the overall film internal stress during processing through volume shrinkage and mechanical stress accumulation. Optimizing this step improves the sidewall adhesion. Irradiation followed by post exposure bake (PEB) leads to an increased degree of cross-linking and stabilization. Since the purpose of the SU-8 matrix is to provide a permanent structural framework for the thermoelectric element, the composite must be hard baked, typically at 150° C.

The SU-8 processing steps and baking times are presented in Table-1. To accommodate the large SU-8 thickness, all baking steps are carried out on a leveled hotplate (by conduction) to avoid dried layer formation on the surface which can hinder diffusion and evaporation of solvent from the interior.

TABLE 1
SU-8 processing steps and optimized baking time for nanowire
array infiltration

| | | Soft | Soft | | | Hard |
|---|---|---|---|---|---|---|
| SU-8 2005 | | bake at | bake at | PEB at | PEB at | bake at |
| Viscosity | Thickness | 6 s · c | 9 s · c | 6 s · c | 95′ C. | 150′ C. |
| (eSt) | (−tm) | (min) | (min) | (min) | (min) | (min) |
| 45 | 40 | 2 | 30 | 1 | 10 | 30 |

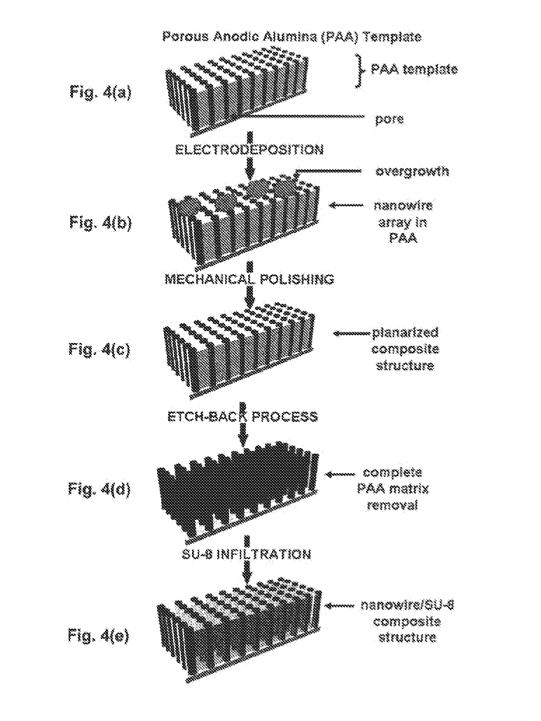

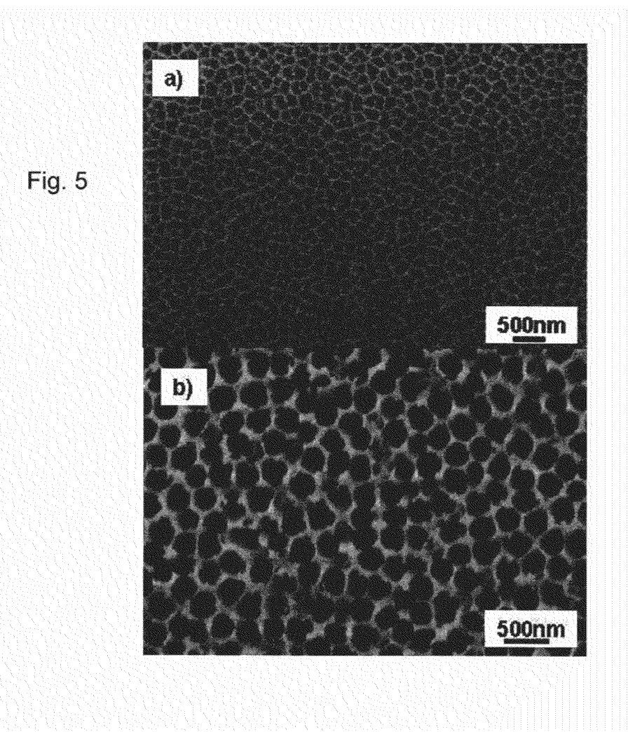

A more detailed process flow for infiltrating SU-8 is shown in animations in FIGS. 4(a)-4(e). FIG. 4(a) shows in animation a PAA template. The commercially available PAA templates, e.g., Whatman's Anodisc 13, can be used in these teachings. These templates have an average pore diameter that is about 80 nm on one side, and about 200 nm on the other. FIGS. 5(a) and 5(b) show these pore sizes for 80 nm and 200 nm, respectively. The layer thickness of the 80 nm pore diameter side extends to about 1-2 μm. The templates are immersed in a 3 wt % KOH/ethylene glycol solution for 5 min, for removal of the bottom 80 nm pore diameter layer as well as for pore widening. The final PAA template has a porosity of about 75%. The templates are then metallized on one side. The preferred side which originally had the 80 nm diameter pores. Different metallic alloys can be used for this purpose. Examples of these metallic alloys are Ti/Pt, Cr/Au or Cr/Ni. The conductive back substrate used in present teachings is Ti/Pt, unless specified. The metallic layer is evaporated using an e-beam evaporator to a total layer thickness of 200 nm. Generally, a 5 nm adhesion layer of either Ti or Cr is evaporated prior to the main metallization. Electrical contacts are then made to the metallized PAA template using conductive silver paint and silver wire, e.g., Ted Pella, 0.05 mm wire diameter. The PAA template is suspended in the electrolyte for at least 4 hrs or overnight prior to electrodeposition of nanowires. Since the templates have high aspect ratios, it is very important for the electrolyte to completely infiltrate the template for uniform pore filling. For better infiltration the electrolyte is stirred at 400 rpm.

FIG. 4(b) shows in animation Bi₂Te₃ nanowires which have been grown by galvanostatic electrodeposition into the PAA template. Electrodeposition in the porous template is achieved by applying a negative potential which is required to start a cathodic current between the ionic species in the electrolyte. Application of this negative potential, thus, reduces the ions at the working electrode to form the desired stoichiometric compound. In order to determine the optimized potential and corresponding current density for BizTe3 electrodeposition on the desired substrate, Cyclic voltammetry (CV) plays an important role in tracing the transfer of electrons during an oxidation-reduction reaction. Bi₂Te₃ nanowires were galvanostatically (constant-current) electrodeposited at a current density of 5 mA/cm² with 3 second pulses. The result of Bi₂Te₃ electrodeposition is nanowires with about 50 μm in length, corresponding to a growth rate of about 5 nm/s.

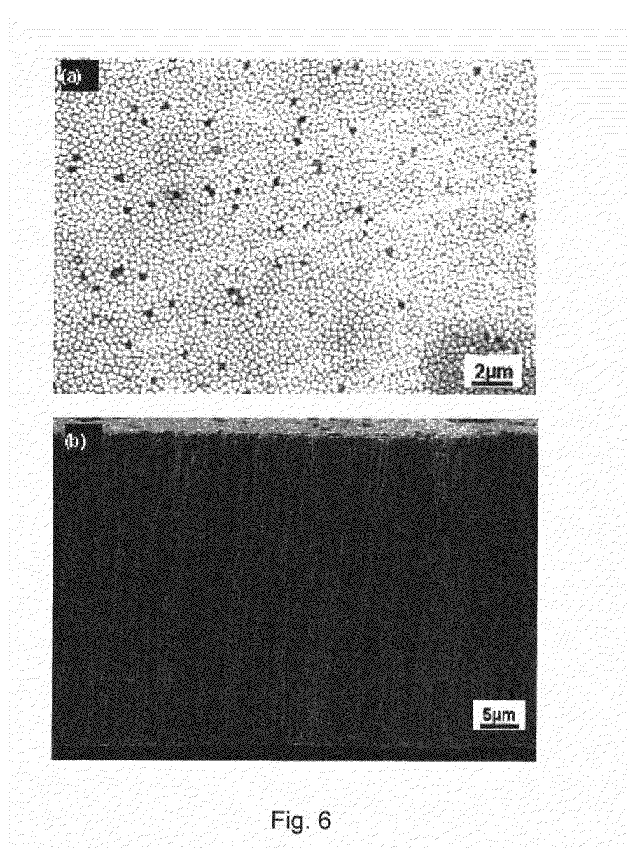

Referring to FIG. 4(c), following Bi₂Te₃ electrodeposition, the nanowire arrays were mechanically planarized to eliminate any overgrowth or non-uniformity in nanowire lengths. FIGS. 6 (a) and 6(b) show FESEM images of planarized Bi₂Te₃ nanowires embedded in the PAA template.

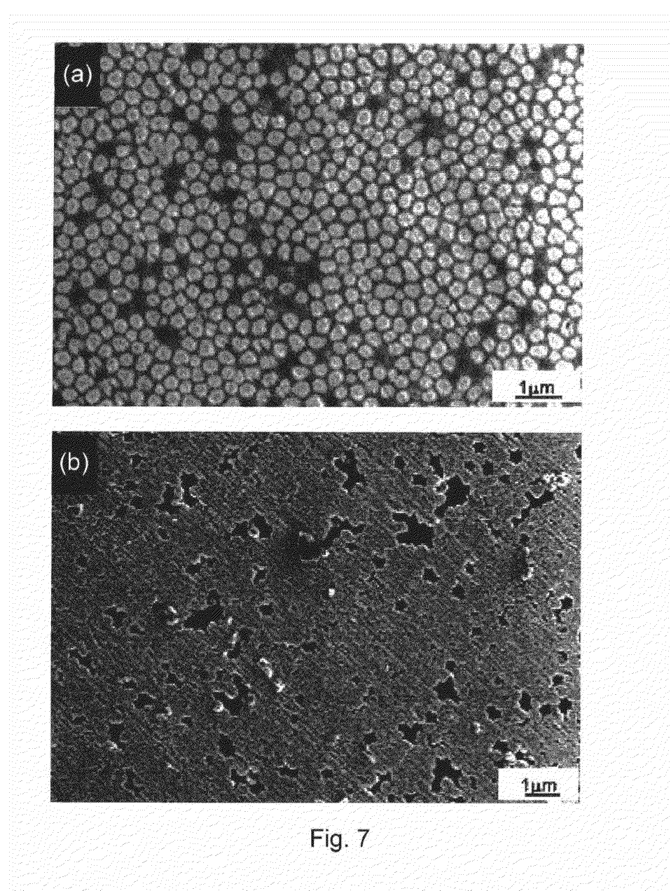

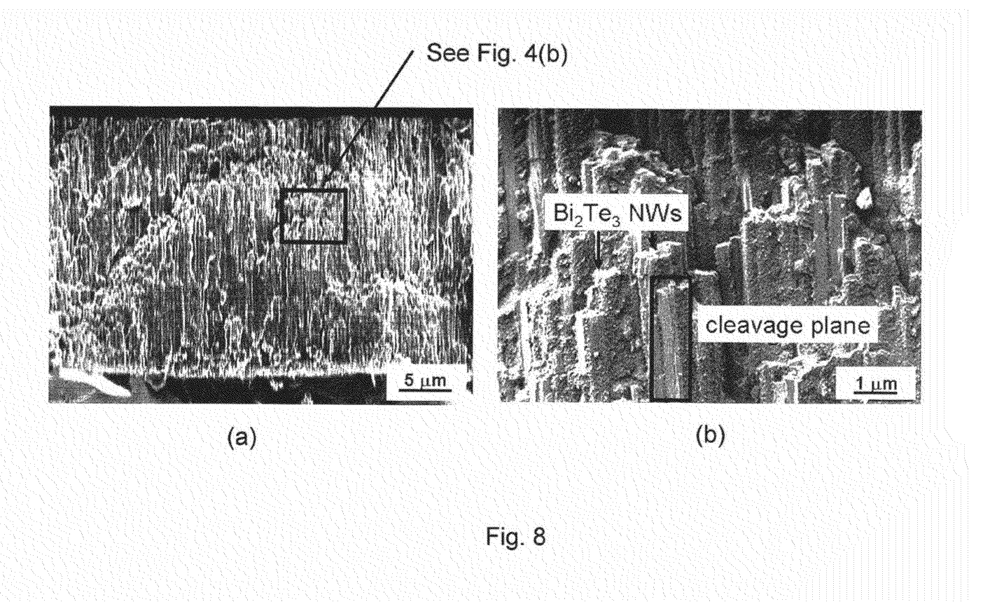

Referring to FIG. 4(d), and as described above, the PAA template is etched back leaving the Bi₂Te₃ electrodeposited nanowires behind. Referring to FIG. 4(e), the SU-8 composite is infiltrated between the nanowires to provide the necessary structural support. FIGS. 7(a) and 7(b) show a comparison between planar views of the nanowires in a PAA template and nanowires embedded in SU-8 composite.

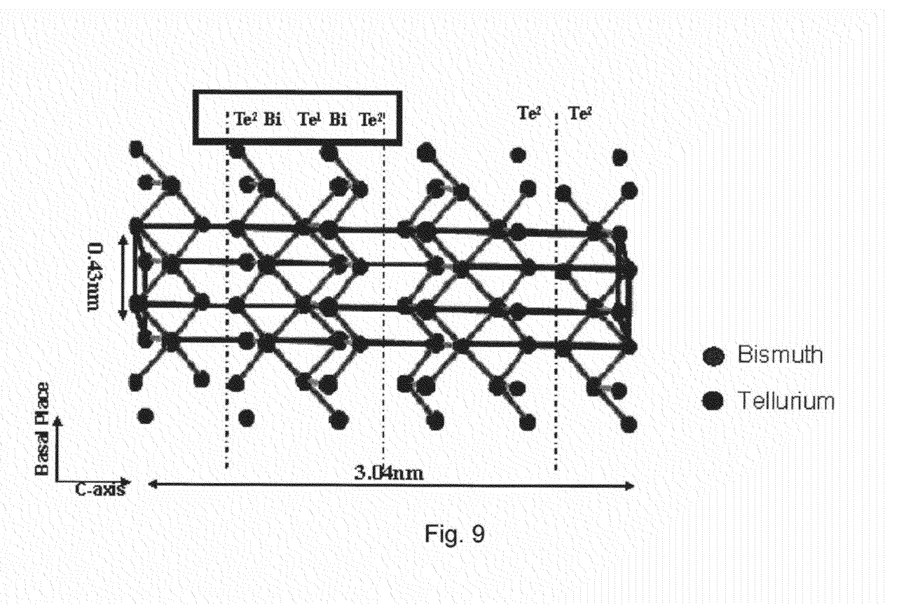

FIGS. 8(a) and 8(b) shows images from scanning electron micrographs of fractured composites. These images confirm complete infiltration of SU-8 epoxy in nanowire array with good adhesion and high structural integrity, required for integration to devices. The crystallographic cleavage plane observed in the fractured nanowire array composites can be attributed to the weak van der Waals bonding between the Te—Te atomic planes in Bi₂Te₃ crystal structure. The weak van der Waals forces between Te—Te atomic planes is further illustrated in the Bi₂Te₃ crystal structure which is shown in FIG. 9. Each atom is surrounded by six atoms, three in the layer below and three in the layer above, along the c-axis. For the atoms in the Te² planes, three atoms from the six nearest neighboring atoms are shared between the two adjacent quintets and hence are slightly further away. In general, longer atomic bond indicate weaker bonds. The bonding between the atoms within a quintet layer is of the covalent-ionic type, which is relatively a stronger bond. However, the interaction between two Te² layers belonging to two different quintet layers is of the van der Waals type. The vertical dashed lines indicate van der Waals bonding between the Te²—Te² atomic planes. This is an important feature in the Bi₂Te₃ crystal structure as they tend to be the weakest plane and thus the plane of fracture.

The resulting nanowires from the process described above were characterized. The nanowire were characterized using various techniques known to those skilled in the art. Examples of these techniques are x-ray diffraction (XRD), energy dispersive spectroscopy (EDS), transmission electron microscopy (TEM) and XRD rocking curve measurements (co scan). The goal of characterization was to determine the degree of mosaicity in fabricating nanowire arrays.

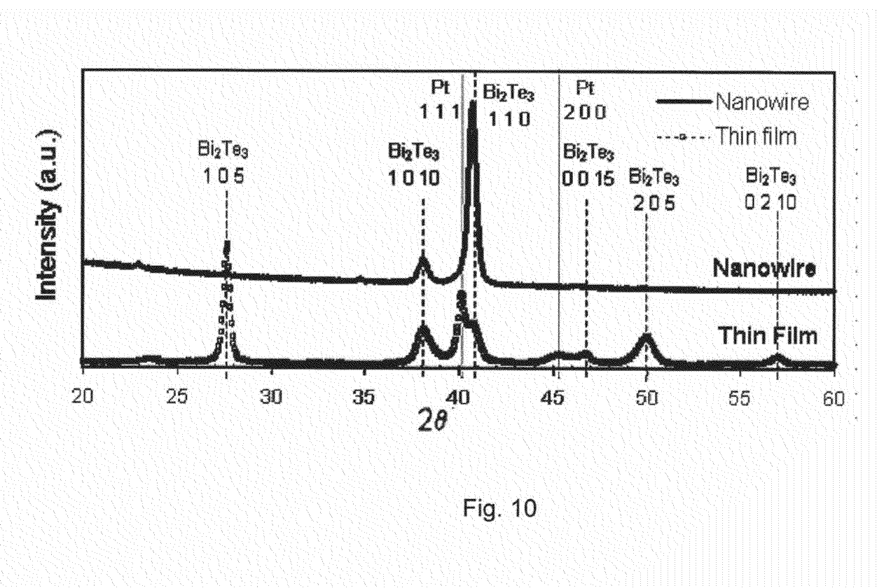

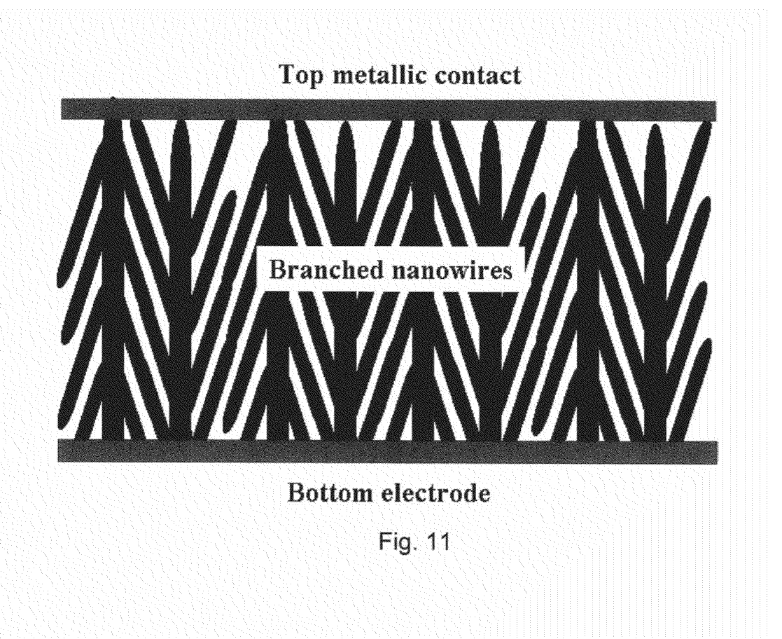

In the first characterization technique using XRD, Bi₂Te₃ thin films and Bi₂Te₃ nanowire array composites were compared. The XRD measurements in this teachings were carried out using a Siemens D500 diffractometer with a Cu Ka source and a high resolution PAN analytical X′ pert system. A comparison of XRD scans of a Bi₂Te₃ nanowire array to a thin film of Bi₂Te₃ synthesized with similar deposition conditions is shown in FIG. 10. Shown in FIG. 10 is that all of the reflections corresponding to the Bi₂Te₃ powder diffraction pattern (JCPDS, 15-0863) appear in the XRD 8-28 scan of Bi₂Te₃ thin film, whereas only the 110 reflection is dominant in the case of the Bi₂Te₃ nanowire array. This confirms a <110> crystallographic fiber texture in the nanowire array.

In the second characterization technique using TEM, inspection of the materials crystal structure, grain size, growth direction, defects, and crystallinity were made. The TEM analysis of Bi₂Te₃ nanowires was performed using a JEOL 2000FX operated at 200 keV. Certain sample preparation steps were required. The Bi₂Te₃ nanowires had to be removed from the PAA matrix, in a manner similar to what was described above. The specific preparation steps are listed below. The nanowire array/PAA composite which is bonded to a Si substrate by Crystal Bond is removed from the substrate by heating the Crystal Bond for easy detachment and acetone cleaning. The Si substrate is separated from the nanowire array composite prior to alumina removal, since KOH etches Si at a much faster rate (0.7)ll'min) than alumina. Then the nanowire array/PAA composite was immersed in an alumina etchant to remove the PAA matrix. The etchant used in this study was 3 wt % KOH. The composite was immersed in the KOH solution maintained at a temperature of 60° C. for 5 hrs, and then rinsed thoroughly in deionized water (DI). At this point substantially all the nanowires were still connected at the bottom to a thin layer of Pt (about 200 nm conductive back electrode required for electrodeposition). To separate the nanowires from the Pt layer, the sample was ultrasonicated in DI water for 60 sec followed by centrifuging for 2 mins. These two processes were repeated multiple times until the nanowires were completely dispersed in the solution. These dispersed nanowires were then transferred on a grid, e.g., a Holey carbon coated 200 mesh Cu, from SPI Supplies. The TEM analysis on such dispersed nanowires confirmed a preferred <110> growth direction.

The thermal characteristics of the nanowire arrays were measured using techniques known to those skilled in the art. Examples of these techniques are the time domain thermo reflectance technique and the photoacoustic technique. In the time domain thermo reflectance technique an incident picosecond pulsed laser beam is split into two beam paths, a “pump” beam and a “probe” beam. The relative optical path lengths between the two beams are adjusted with a mechanical delay stage. The thermal conductivity of Bi₂Te₃ nanowire array/PAA composites was determined to be 0.9-1.2 W/m-K. The photoacoustic measurement showed a thermal conductivity value of 1.4 W/m-K for Bi₂Te₃ nanowire array/PAA composite. The thermal conductivity of the PAA matrix alone was measured as 0.38 W/mK. Estimating the thermal conductivity of the Bi₂Te₃ nanowire array/PAA composite to be an arithmetic average of the thermal conductivities of Bi₂Te₃ and the PAA, it is possible to calculate the contribution to thermal conductivity from the PAA material alone. Taking into account that the porosity of the PAA template was 70%, the effective PAA thermal conductivity is 1.21 W/m-K. This value can be used to back calculate the contribution from the Bi₂Te₃ nanowires in the composite, which is calculated to be 1.48 W/m-K.

Although the thermal conductivity is an important factor in ZT, it is well known to those skilled in the art that additional measurements are required to evaluate ZT. ZT can be evaluated directly by building a p-n couple and measuring the cooling or power generation performance. ZT can also be measured with a single element by performing a transient ZT measurement using the Harman technique. Alternatively, the individual properties—Seebeck coefficient, thermal conductivity and electrical conductivity—can be measured on the same material to estimate ZT. Such measurements require great care to account for parasitic thermal and electrical effects, including contact resistance, temperature drops in contacts and bonding material, and thermal convection if measured in air. These complications are especially severe for thin films or very thin (<100 micron) bulk materials.

Additionally, thermal conductivity measurements on BhTe3 nanowire array/SU-8 composites in reference with Bi₂Te₃ nanowire array/PAA composites were performed. The measurement used the time domain thermo-reflectance technique. The Bi₂Te₃/PAA composite was used as a baseline for comparison purposes. The measured effective thermal conductivity in the BhTe3 nanowire array/PAA composite was in the range of 0.9-1.2 W/m-K. The measured effective thermal conductivity of Bi₂Te₃ nanowire array/SU-8 composite was in the range of 0.1-0.2 W/m-K. Thus, an order of magnitude reduction in the effective thermal conductivity of the composites was demonstrated by replacing the PAA matrix (κ=1.2 W/m-K) with a lower thermal conductivity matrix, SU-8 (κ=0.2 W/m-K).

### 3-D Interconnected Nanowire Array

A challenge associated with the polymer infiltration approach is that polymers begin degrading at relatively low temperatures. For example the SU-8 begins to degrade at about 350° C. At the same time, low temperature gradient negatively affects power generation. Therefore, it would be desirable to achieve a configuration that eliminates the parasitic thermal shunt of the PAA template while allowing a large thermal gradient between the cold and hot reservoirs.

An alternate approach for reducing the parasitic thermal shunt of the PAA template is fabrication of a 3-D self-supporting branched nanowire array. FIG. 11 shows in animation a self-supported nanowire array with the template removed. Therefore, in order to fabricate such a self-supported nanowire array, a template with a 3-D network of branched pores is needed. A branched PAA template can be used to serve as a sacrificial framework for the self-supporting nanowire array. The nanowires are electrodeposited into the branched PAA template. The template is then etched away. However, such a branched porous template is not commercially available. The conventional PAA templates have cylindrical, vertical and spatially ordered pores, as was shown in FIGS. 5(a) and 5(b). What is needed, however, is a branched template that can be used to produce the self-supporting structure shown in the animation of FIG. 11.

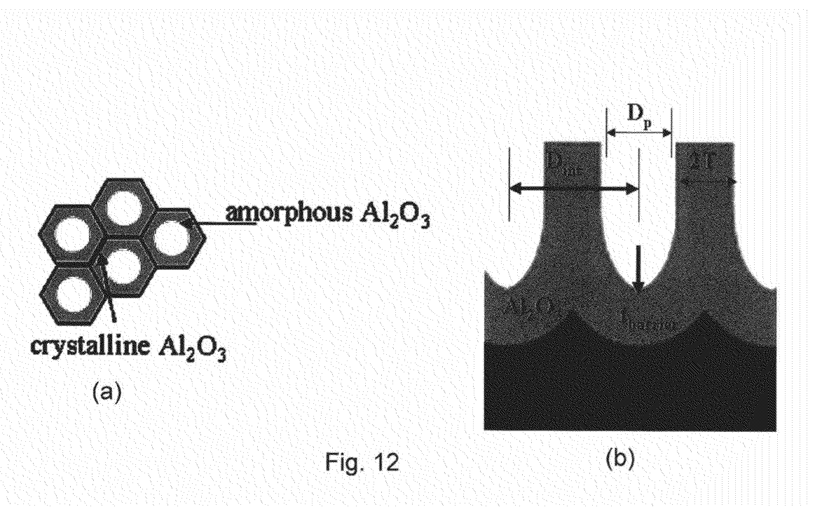

Before the formation of the branched template is described, formation of commercially available PAA template is described. Traditionally, the method for fabricating PAA templates involves anodic oxidation (anodization) of aluminum foil or films in a slightly acidic electrolytic bath. The simultaneous oxidation and dissolution of aluminum leads to formation of aluminum oxide (alumina) with self-ordered, vertical pores in a hexagonal arrangement. This formation results in a scalloped bottom region known as the barrier oxide. Example of this process is shown in FIG. 12. The ordered arrays of PAA can be obtained within three growth classes. The first is using sulfuric acid at 25 V for an average interpore distance (shown as Dᵢₙₜ) of about 60 nm, and pore diameter (shown as Dₚ) of about 20 nm. The second growth class uses oxalic acid at 40 V for Dᵢₙₜ of about 100 nm and Dₚ of about 50 nm. The third growth class is phosphoric acid at 195 V for Dᵢₙₜ of about 500 nm and Dₚ of about 200 nm.

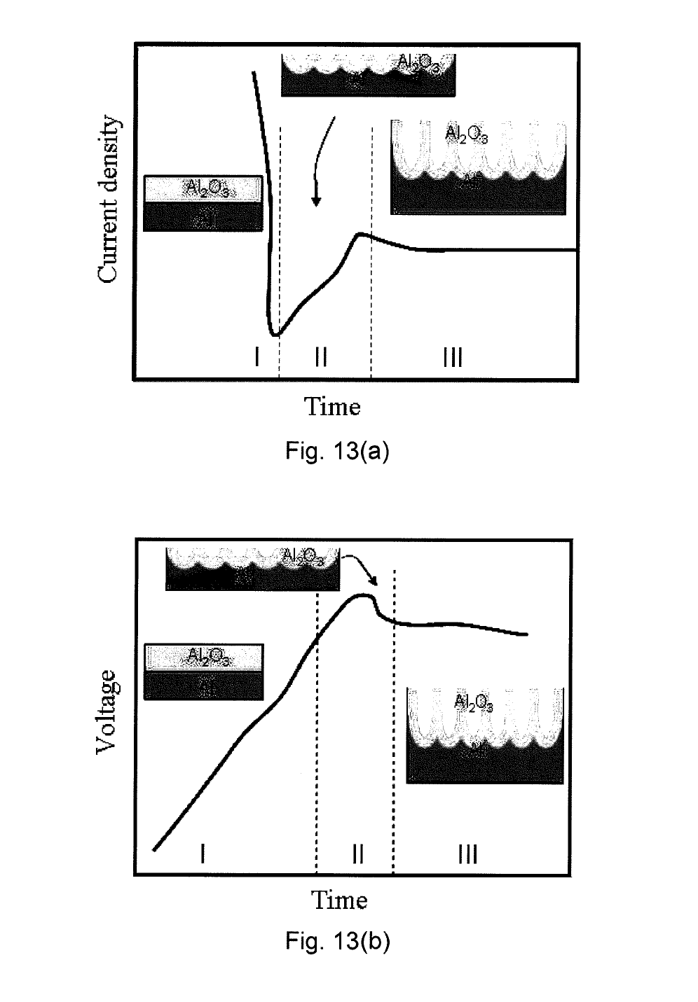

The PAA template formation can be under a constant current condition or under a constant voltage condition. Generally, if a constant current source is used, FIG. 13(a), the current decreases exponentially with time (with increase in oxide layer thickness) and reaches a low steady current value after a substantial amount of time. Referring to FIG. 13(a) the constant voltage graph is divided into three phases, I, II, and III. In phase I, the current decreases rapidly for a short period of time due to formation of initial barrier oxide layer. In phase II after a period of time which is associated with pore formation, the current increases and reaches steady values at the boundary of phases II and III. The increase in current after pore formation, in phase II, can be associated with increase in the active surface area due to the pores. Referring to FIG. 13(b), the constant current condition graph is also divided into three phases. In phase I the voltage increases linearly with time until a critical potential value where transition from barrier oxide to PAA occurs. In phase II, the voltage decreases slightly and then reaches a steady state. In phase III the steady state corresponds to pore stabilization and growth.

The optimum potential for self ordering of pores in PAA in various electrolytes such as sulfuric acid, oxalic acid and phosphoric acid is known to those skilled in the art. The fabrication of PAA with self-ordered pores is referred to mild anodization (hereinafter, “MA”). Typical MA growth rates are 2-5 μm/hr. Conversely, the fast fabrication of PAA is called hard anodization (hereinafter, “HA”). Typical HA growth rates are about 25-35 times faster than MA. For example, aluminum can be hard anodized in sulfuric acid solution on application of a potential of 70 V and a current density of 200 mAcm⁻². Conversely, mild anodization would require a potential of 25 V and current density in the range of 2-4 mAcm⁻². Similarly hard anodization in oxalic acid solution requires a potential of 140V and a current density of 30-250 mAcm⁻², whereas mild anodization would require a potential of 40 V and current density of about 5 mAcm⁻². The MA process using a potential range of 160-195 V enables vertical pores with average pore diameter Dₚ of about 200 nm and interpore spacing Dᵢₙₜ of about 500 nm.

In accordance with these teachings, fabrication of three-dimensional branched porous anodic alumina (hereinafter, “B-PAA”) templates is provided. The B-PAA is prepared by anodization of aluminum in a phosphoric acid electrolyte maintained at an initial bath temperature of 4° C. The two electrolytic concentrations explored were 0.3 M and 0.4 M. The experiments were conducted at two potential conditions corresponding to the extreme potentials of the self-ordering category in phosphoric acid electrolytes, 160 V and 195 V, respectively. The influence of current density was observed by using two current limiting conditions, 1.1 A/cm² (maximum limit) and 4 mA/cm² (lower limit). A temperature rise in the electrolytic bath was observed during the B-PAA formation from an initial value of 4° C. to about 90° C.

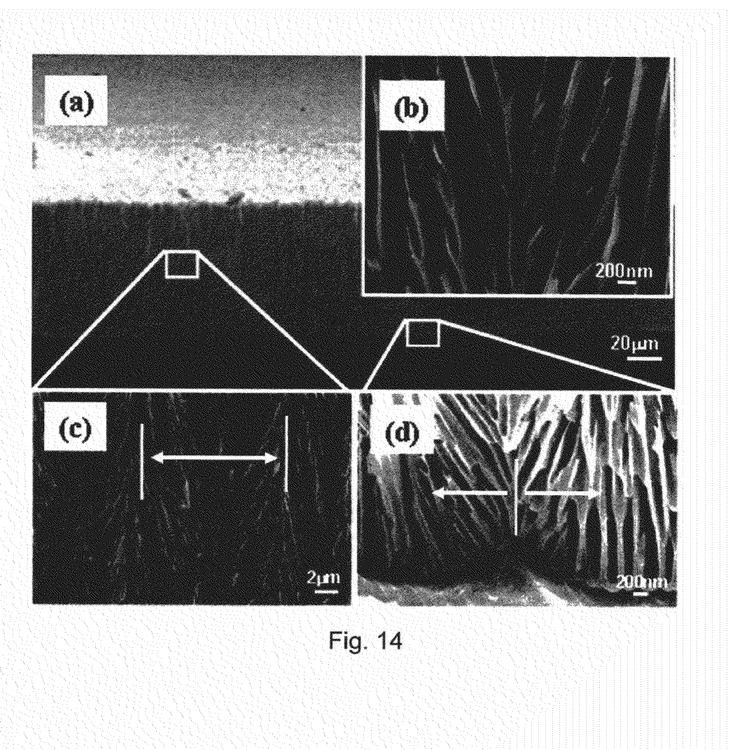

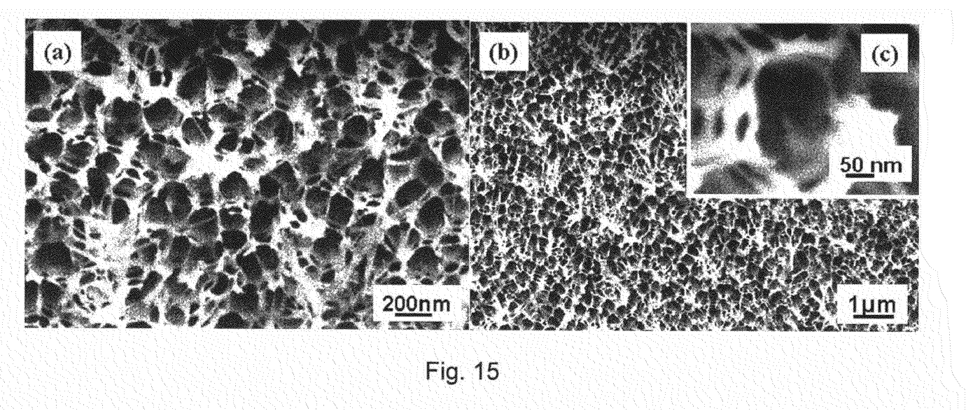

In one embodiment the BPAA template was formed in accordance with the following steps. A 250 μm thick foil aluminum with high purity, e.g., 99.9995% purity (obtained from PVD Materials Corp.) was cleaned with acetone and methanol and then electropolished in a solution composed of 5 vol % sulfuric acid, 95 vol % phosphoric acid, and 20 g/L chromic oxide at a potential of 20 V for 20 sec. After electropolishing both sides, the aluminum foil was anodized in 0.4 M phosphoric acid maintained at 4° C. using a potential of 160 V and a current density of 1.1 A/cm². These electrochemical conditions led to formation of branched porous anodic alumina film (B-PAA) with a growth rate of 300 μm/hr, i.e. 60 times faster than the conventional PAA template by MA process (5 μm/hr). The resulting B-PAA template is shown in FIGS. 14 and 15. The temperature of the electrolytic bath increased from 4° C. to 90° C. during the formation of B-PAA indicating an exothermic reaction. The reaction in the electrolyte was vigorous evidenced by evolution of hydrogen gas at the cathode (Pt electrode). The anodization was stopped after 20 minutes. After the anodization step, the non-anodized aluminum at the bottom of the B-PAA template was removed by floating the sample in a solution composed of 10 wt % mercury dichloride for 4 hrs. The scalloped region at the bottom of each pore is closed and is referred to as the barrier layer. To utilize the B-PAA templates for electrodepositing nanowires it is essential to remove the barrier layer at the bottom of pores. The open channels in the B-PAA template will facilitate the infiltration of electrolyte required for uniform growth of nanowires. The barrier oxide at the bottom of the pores in the alumina film was removed by immersing the sample in a solution composed of 1% dilute phosphoric acid for 15 min followed by mechanical polishing on both sides.

Referring to FIG. 14(a), a cross-sectional FESEM image of a approximately 100 μm thick interconnected B-PAA template is shown. A higher magnification image of cross-sectional B-PAA, shown in 14(b) confirms the branched network of pores with average pore diameters of the order of 200 nm and pore wall thickness about 20 nm. Referring to FIG. 14(c), a representative cross-sectional image corresponding to the middle of a B-PAA template which indicates the three-dimensional network of pores that is quasi-periodic throughout the template is shown. Referring to FIG. 14(d), a cross-sectional image of the bottom of the B-PAA template—the metal/oxide interface shows vertical and inclined scallops (barrier layer) at the bottom of each pore (about 500 nm). A higher degree of quasi-periodic scalloping effect is seen throughout the interface (corresponding to a spatial periodicity of about 5 μm. The formation of vertical scallops (barrier layer) at the bottom of each pore is generally observed in conventional PAA synthesized by mild anodization. The secondary pores branch at an angle from the main vertical pore. The secondary branching of pores leads to the formation of inclined scallops. The inclined scallops and the formation of larger quasi-periodic scallops at the metal/oxide interface is a characteristic of a B-PAA template.

The interpore spacing and pore wall thicknesses of these branched pores varies with the duration of growth and location in the template (i.e. top or bottom of the template). An image analysis tool was used to determine the average dimensions at the top and the bottom of the B-PAA template for growth durations of 10 sec, 30 sec, 60 sec and 3 min and the data is presented in table 3.

TABLE 3
Pore diameter Dₚ, interpore spacing Dᵢₙₜ, and pore wall thickness
Dₜₕₖ at the top and bottom of a B-PAA template at different growth
durations determined by image analysis.

| Location | Dimension | 10 sec | 30 sec | 60 sec | 3 min |
|---|---|---|---|---|---|
| | Height | 7 | 14 | 19 | 27 |
| Top | DP (nm) | 157 | 134 | 207 | 145 |
| | Dint (nm) | 252 | 266 | 293 | 389 |
| | Dthk (nm) | 65 | 54 | 17 | 9 |
| Bottom | DP (nm) | 109 | 107 | 130 | 190 |
| | Dint (nm) | 474 | 302 | 367 | 286 |

Referring to FIG. 15, the top surface of the B-PAA template (surface facing the electrolyte) shows a quasi-periodic thinning along the crystalline AlzO3 pore wall in the growth direction. A quasi-periodic thinning is observed along the crystalline Al₂O₃ pore wall in the growth direction. These local thinner oxide regions along the vertical pore wall act as potential region for secondary branching. Each cell-comprising of vertical pore and Al₂O₃ pore wall—has six cell walls. The secondary pores originate from the hexagonal cell wall of the crystalline Al₂O₃ leading to a network of branched pores.

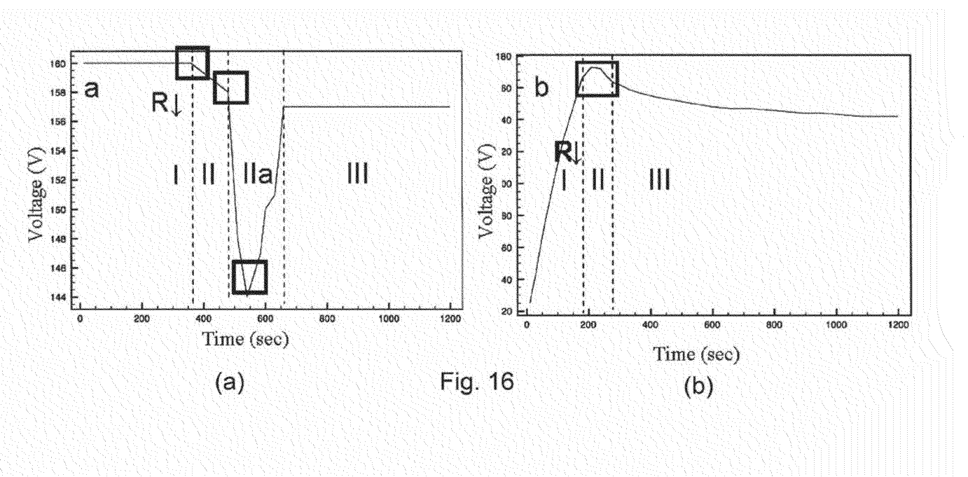

The physical phenomena occurring during the oxide growth, i.e. primary and secondary pore formation can be explained using potential and current transients. FIGS. 16(a) and 16(b) presents the potential transients for B-PAA formation under high current density of about 1.1 A-cm⁻² in comparison to conventional mild anodization in a phosphoric acid electrolyte at a low current density of 4 mA-cm⁻². The onset of B-PAA formation, in some cases, was delayed by 5-8 min which can be attributed to variation in sample and electrode preparation. An example of a delayed onset of B-PAA formation is presented in FIG. 16(a).

As shown in FIG. 16(a), there are four stages of growth. Stage I includes an initial delay period up to 360 sec due to sample preparation and formation of barrier oxide. The onset of the reaction is indicated by the temperature rise of the electrolytic bath. A critical period occurs at 380 sec beyond which there is a drop in the voltage. This drop in voltage corresponds to the transition from barrier oxide to porous oxide. The initiation of primary pores marks the Stage II of B-PAA formation. Due to the initiation of pores there is an increase in surface area which causes a simultaneous rise in current. The current increases and reaches the maximum limit set in these teachings (I=3.25 A). At this point, the conditions switch from constant potential to current limited state. In a conventional PAA, the voltage eventually reaches a steady state due to equilibrium between the field enhanced dissolution at the base of the pore and oxidation at the M/O interface which indicates the existence of a constant thickness of barrier layer (t_{barrier}). The constant barrier layer thickness leads to the growth stabilization and formation of vertical pores, which would correspond to Stage III in a conventional PAA. The high current density (1.1 A-cm⁻² in these teachings) triggers a second drop in the voltage at 480 sec. This drop in voltage corresponds to secondary perturbations on the oxide surface. The perturbations show a quasi-periodic selection of vertical pores on which the secondary pores originate. The formation of secondary pores occurs along the pore walls of the main vertical pore. The primary and the secondary pores have different barrier layer thicknesses at the bottom of the pore. There is a continued drop in the voltage corresponding to tertiary branching as well as secondary and tertiary branch merging. This voltage drop corresponds to Stage IIa of B-PAA formation. An equilibrium state is reached when the barrier layer thickness at the bottom of all primary and secondary pores becomes equal leading to pore stabilization. Due to constant barrier layer thickness the voltage reaches a steady state at 660 sec corresponding to Stage III of B-PAA formation. The equilibrium between the field enhanced dissolution at the base of each pore in B-PAA and oxidation at the M/O interface leads to growth stabilization of both primary and secondary pores.

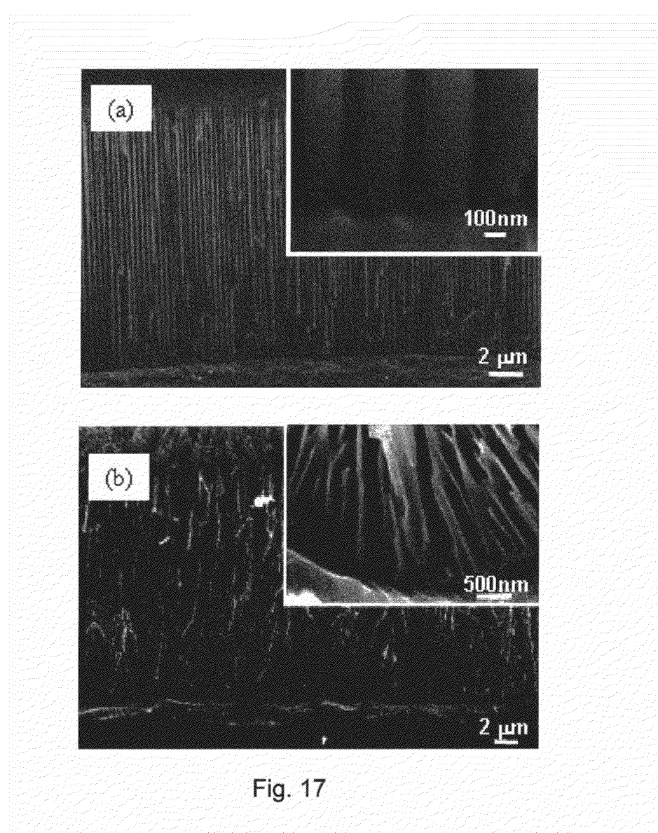

Referring to FIG. 17, FESEM images present the two stages of B-PAA formation—Stage II: primary pore initiation and vertical pore growth and Stage I1a: transition from primary vertical pore formation to secondary branched pore formation. The image reveals the quasi-periodic selection of vertical pores on which the secondary pores originate.

The pore formation and growth mechanism was monitored and characterized at every 10 second intervals up to 3 minutes using field emission scanning electron microscopy (FESEM). At time=O the onset of primary pore formation is indicated by the first voltage drop in the potential transient. The influence of the applied potential (160 V and 195 V), maximum current density (1.1 A/cm² and 4 mA/cm²), electrolyte concentration (0.3 M and 0.4 M), and initial electrolytic bath temperature (4° C. and 90° C.) on B-PAA formation were investigated. In all the cases, the starting AI foil sample area was 1 cm×3 cm with thickness 250 μm. The Al foil was electropolished on both sides to make the surface morphology smooth. The electropolished Al foil was placed facing the counter electrode (Pt mesh) at a distance maintained at 2 cm. In these teachings, the side facing the counter electrode is referred as the ‘top side or S1’ and the other side as the ‘back side or S2’.

CASE 1 conditions:

| | |
|---|---|
| Applied potential | 160 V |
| Current density | 1.1 A/cm² |
| Phosphoric acid | 0.4M |
| Initial temperature | 4° C. |

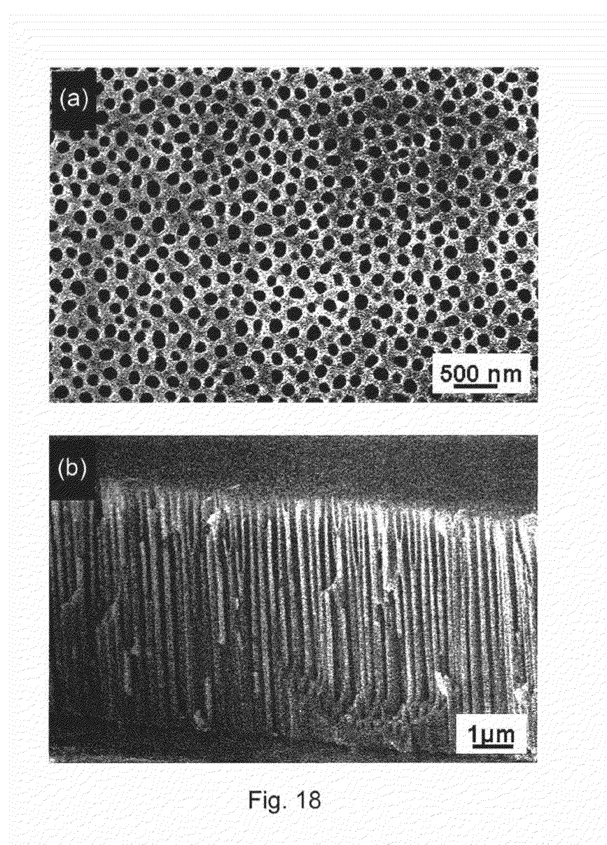

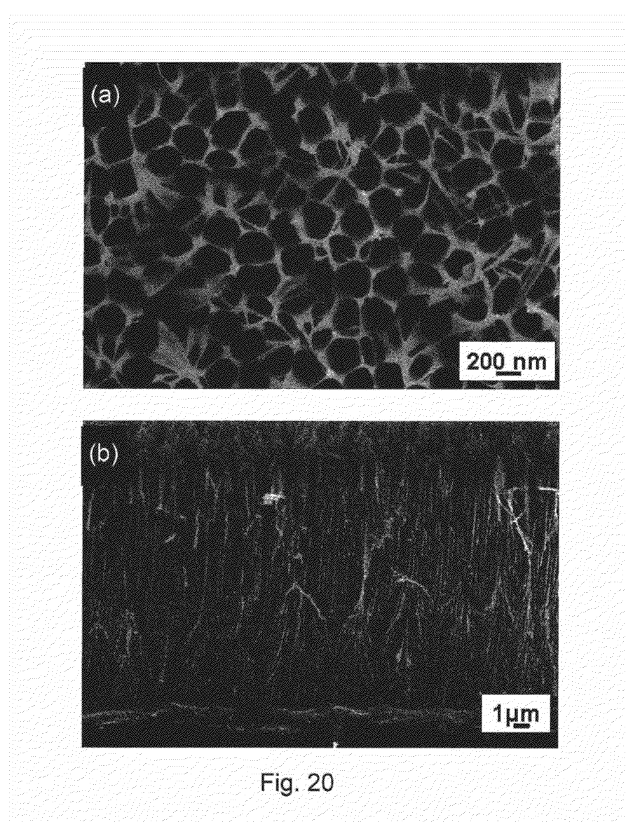

The FESEM images shown in FIG. 18 corresponding to 10 sec growth duration indicated that the thickness of S1 was 6 μm and S2 was 2 μm. The pore ordering in the case of S1 was better than that of S2 as judged by inspection. FIGS. 18, 19 and 20 correspond to 10 sec, 30 sec and 60 sec growth durations, respectively.

### CASE 2 Conditions:

| | |
|---|---|
| Applied potential | 160 V |
| Current density | 1.1 A/cm² |
| Phosphoric acid | 0.3M |
| Initial temperature | 4° C. |

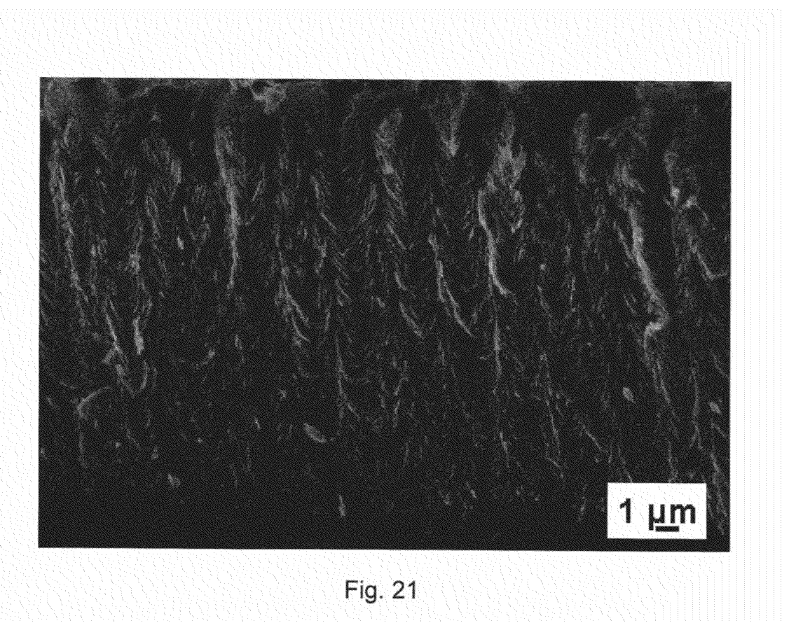

FESEM image of cross-sectional view of B-PAA in 0.3 M phosphoric acid for a growth duration of 7 min for conditions of Case 2 is shown in FIG. 21.

### CASE 3 Conditions:

| | |
|---|---|
| Applied potential | 160 V |
| Current density | 1.1 A/cm² |
| Phosphoric acid | 0.4M |
| Initial temperature | 90° C. |

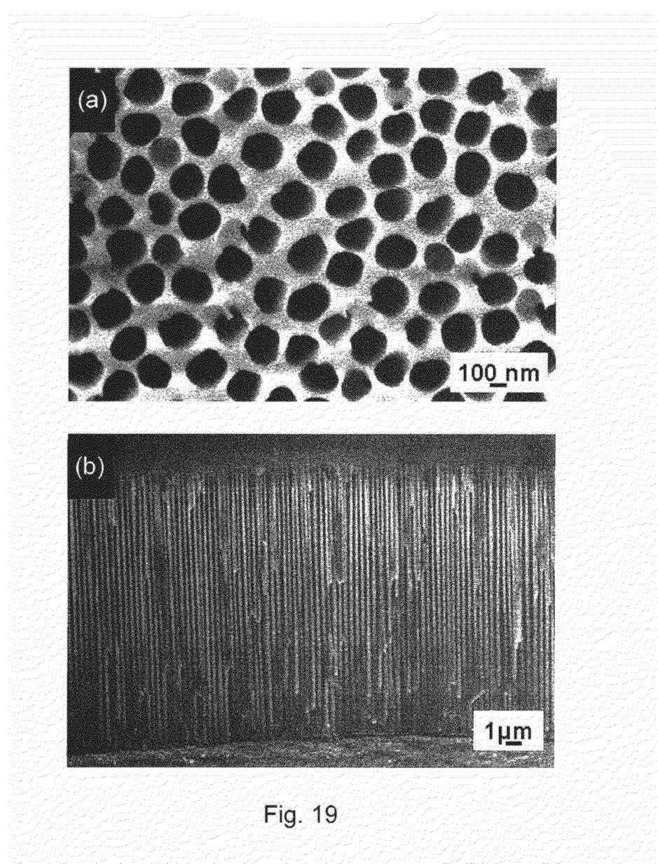

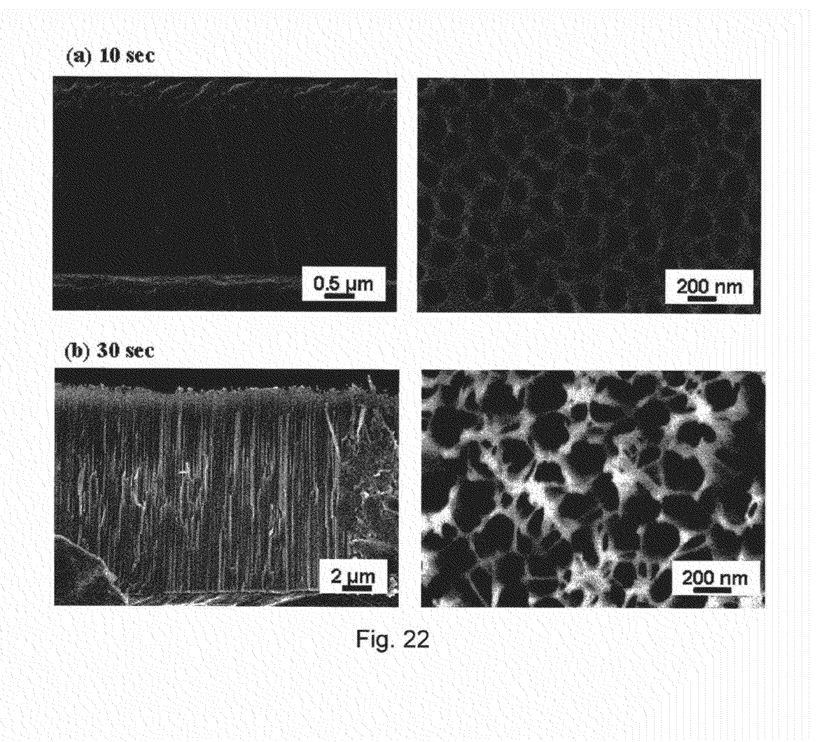

The formation of B-PAA starts almost instantaneously when the initial temperature of the electrolytic bath is maintained at 90° C. The FESEM images in FIG. 22 present the cross-sectional and plan view of B-PAA where the anodization process was stopped after (a) 10 sec and (b) 30 sec. FIG. 22(a) indicates the formation of vertical pores of thickness of about 3 μm and Dₚ about 150 nm. The thickness of the vertical pores increases to 15 μm and Dₚ increases to about 200 nm after 30 sec (See FIG. 22(b)). In comparison to FIG. 19, B-PAA formation at 4° C. and growth duration 30 sec—the amount of Al₂O₃ dissolution is much higher in the case of B-PAA formation at 90° C. which is evident from the plan view in FIG. 422(b).

### CASE 4 Conditions:

| | |
|---|---|
| Applied potential | 160 V |
| Current density | 4 mA/cm² |
| Phosphoric acid | 0.4M |
| Initial temperature | 4° C. |

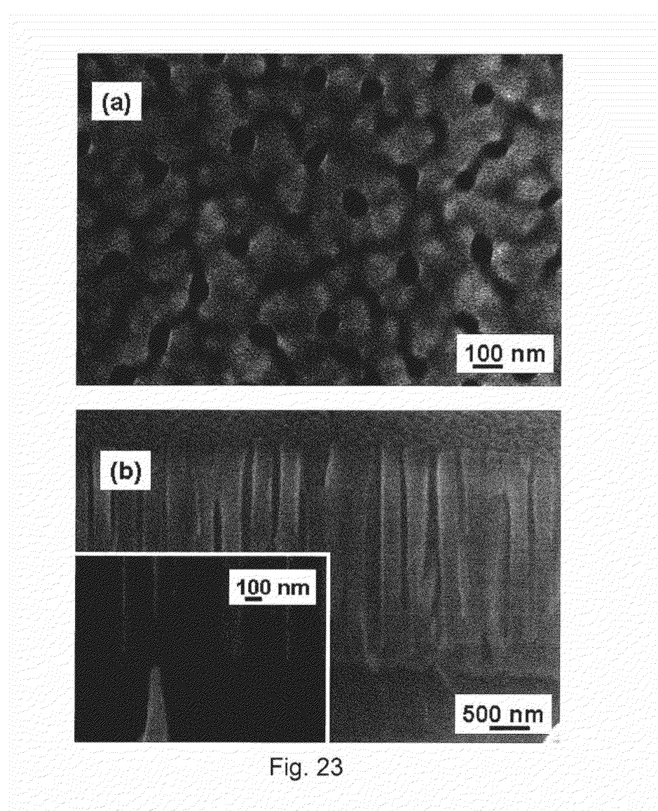

When the current in the B-PAA experiment is limited to a low current value of 0.01 A (current density of about 4 mA//cm²), conventional PAA is formed. The experiment was continued for a growth duration of 60 min. Plan and cross-sectional FESEM images (See FIG. 23) indicate the formation of conventional PAA with a vertical pore thickness of about 2.5 μm, average pore diameter Dₚ of about 55 nm, interpore spacing Dᵢₙₜ of about 160 nm (at the top surface) and Dᵢₙₜ of about 400 nm (at the bottom surface) and barrier layer thickness t_{barrier} of about 170 nm.

### CASE 5 Conditions:

| | |
|---|---|
| Applied potential | 195 V |
| Current density | 1.1 A/cm² |
| Phosphoric acid | 0.4M |
| Initial temperature | 4° C. |

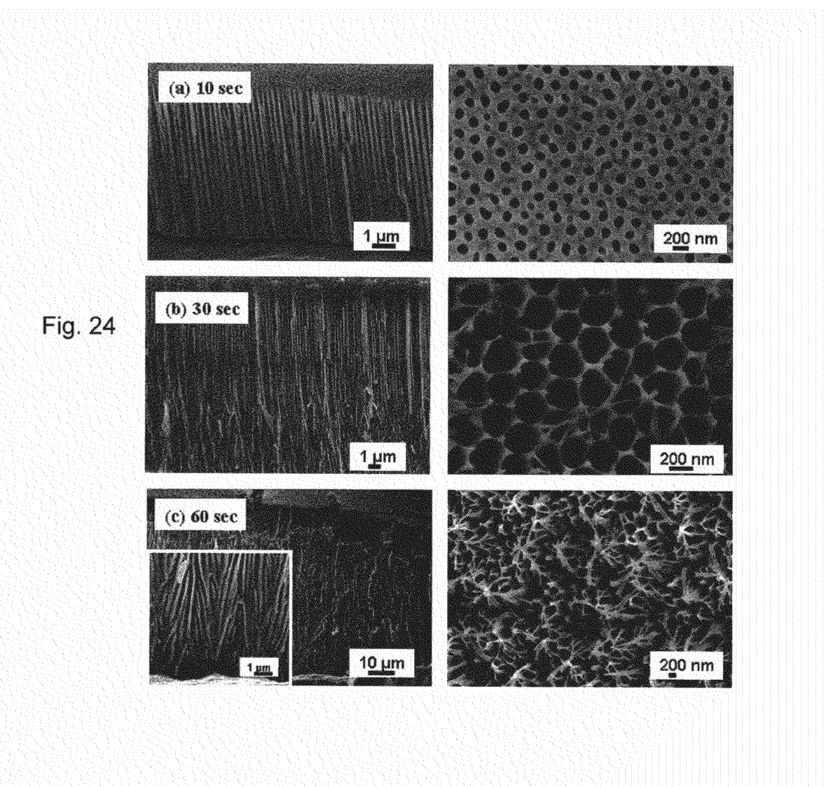

The anodization potential in this experiment was held constant at 195V. The growth was monitored at 10 sec, 30 sec and 60 sec. Cross-sectional and plan view FESEM images of B-PAA are presented in FIG. 24. FESEM images corresponding to growth duration: (a) 10 sec, indicates the formation of vertical pores of thickness of about 5 μm, Dₚ of about 100 nm, Dᵢₙₜ of about 260 nm; (b) 30 sec: indicates the transition from vertical pores to secondary branching with of about 10 f-lm vertical pores and of about 5 f-lm branched pores, Dp of about 260 nm, Dint of about 270 nm and (c) 60 sec: indicates of about 50 μm thick branched pores, Dₚ of about 260 nm. The dissolution process is very vigorous and the top vertical pore layer is completely etched away and cannot be seen in FIG. 24(c).

### Compositionally Modulate Two Material, Such as Bi₂Te₃/Bi₂Se₃

Complex material structures in nanowire morphology provides higher ZT numbers. It is possible to emulate complex material structures in nanowire morphology via electrodeposition. However, to be able to synthesize these complex nanostructures in a single electrochemical bath is non trivial. To date there has been no demonstration of an n-type nanowire array fabrication of multilayer nanowires by varying electrodeposition potentials from a single electrolytic bath, with the Bi₂Te₃/BiSe₃ material system.

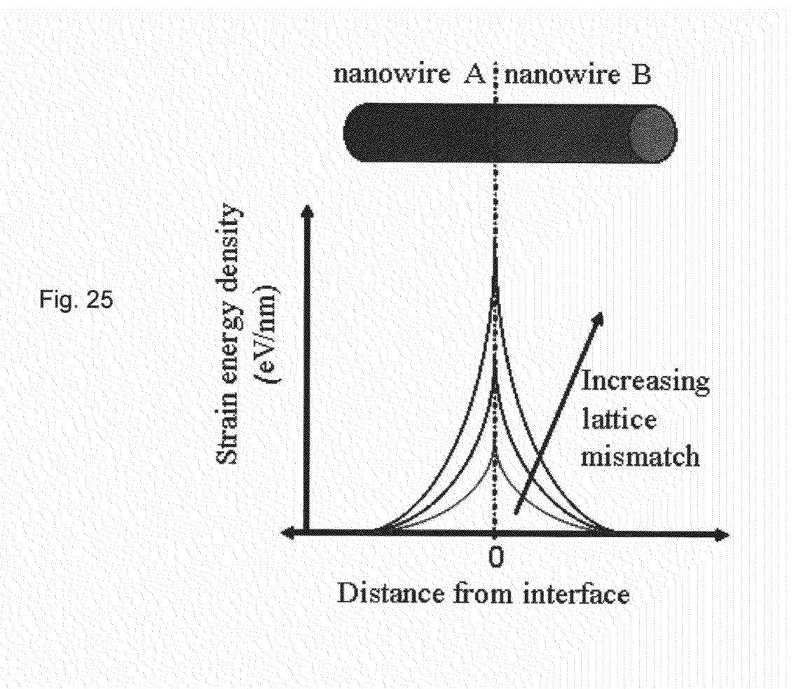

The interest in nanostructuring Bi₂Te₃ alloys for the device operation temperatures near room temperature exists since their bulk counterparts have already been established as relatively high efficiency thermoelectric materials with ZT values of up to 1.4. The highest ZT's in bulk Bi₂Te₃ alloys to date have been observed in p-type BiₓSb₂₋ₓTe₃ and n-type Bi₂(Se_{0.1}Te_{0.9})₃ The occurrence of natural nanostructuring in Bi₂Te₃ materials system, with a periodicity of 10 nm parallel to crystallographic 10.10 planes, make Bi₂Te₃ materials attractive, assuming that the properties can be further improved by artificial nanostructuring. There are reports of fabrication of epitaxial nanostructured materials such as Bi₂Te₃/Sb₂Te₃ thin-film superlattices which exhibit high ZT value of 2.4 at room temperature. However, the viability of these thin-film structures for device purposes is limited by the scalability of the growth technique (molecular beam epitaxy (MBE) in this case) and by the elastic constraints imposed by thin-film epitaxy of lattice mismatched materials on a macroscopic substrate. It has been shown that a p-type Bi₂Te₃/Sb₂Te₃ superlattice, where the component materials have a lattice mismatch of 3%, can be grown epitaxially and this materials system exhibits a ZT value of 2.4 at room temperature. However, the n-type counterpart, Bi₂Te₃/Bi₂SeₓTe₃₋ₓ superlattice exhibited a very low ZT value of 0.6 at room temperature. The Bi₂Te₃/Bi₂Se₃ materials system is a potential candidate for the n-type counterpart but a large lattice mismatch of 5.6% between the component materials limits growth of these materials in thin film form. Such large lattice mismatches can be elastically accommodated in nanowires due to lateral lattice relaxation. Initially, a case where nanowire B is grown on nanowire A is considered (See FIG. 25). The strain energy density decreases exponentially away from the interface along the nanowire axis. Thus, in case of nanowires the strain energy density decreases and there is a minimal increase in strain energy with thickness. Whereas, in thin films the strain energy density is constant and the strain energy increases linearly with thickness.

Hence, these teachings focus on Bi₂Te₃/Bi₂Se₃ material system where there is a need for a high efficiency low temperature thermoelectric material in the thermoelectric materials chart over the range of thermoelectric device operation temperatures.

A representative quintet in the BhSe3 crystal structure has alternate layers of Se and Bi atoms i.e.—[Se²—Bi—Se¹—Bi—Se²]—, however the bond lengths between the atoms in Bi₂Se₃ are shorter than those of Bi₂Te₃. Shorter bond lengths correspond to stronger bonds, i.e. higher bond strengths and larger bandgaps. Since the bond lengths in Bi₂Se₃ are shorter than Bi₂Te₃, the bandgap in Bi₂Se₃ is larger than Bi₂Te₃. The bandgap and Debye temperature of Bi₂Se₃ are 0.97 eV, 185±3K, respectively. Hence, alloying Bi₂Te₃ with Bi₂Se₃, offers a two fold advantage, (a) the possibility of reduction in thermal conductivity due to introduction of additional scatterers and (b) tuning the energy band gap, i.e. an increase in bandgap can accommodate the higher device operation temperature with enhanced efficiencies.

The experimental setup for co-deposition of Bi—Te—Se ternary compounds from a single electrolytic bath is similar to that for synthesis of Bi₂Te₃ material system. The only difference is the electrolytic bath, which contains three types of ionic species, Bi, Te and Se. The electrodeposition recipe for Bi₂SeₓTe₃, is known in the art for thin film deposition of Bi₂SeₓTe₃₋ₓ.

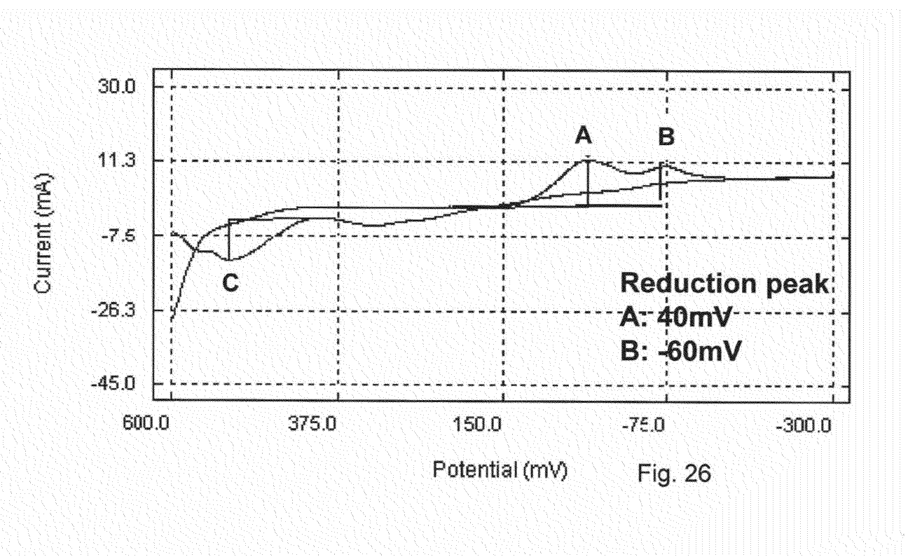

The electrolyte composition includes 10 mM Bi (Bi(NO₃)₃), 10.3 mM HTeO₂⁺(H₂TeO₃) and 1 mM Se⁴⁺(H₂SeO₃) dissolved in 1 M HNO₃. For determining the optimized potential required for electrodeposition of Bi₂SeₓTe₃, nanowires, cyclic voltametry was performed on PAA templates with Pt back electrodes. A typical cyclic voltammogram for the Bi—Te—Se system on a Pt substrate is presented in FIG. 26, where current is plotted as a function of potential.

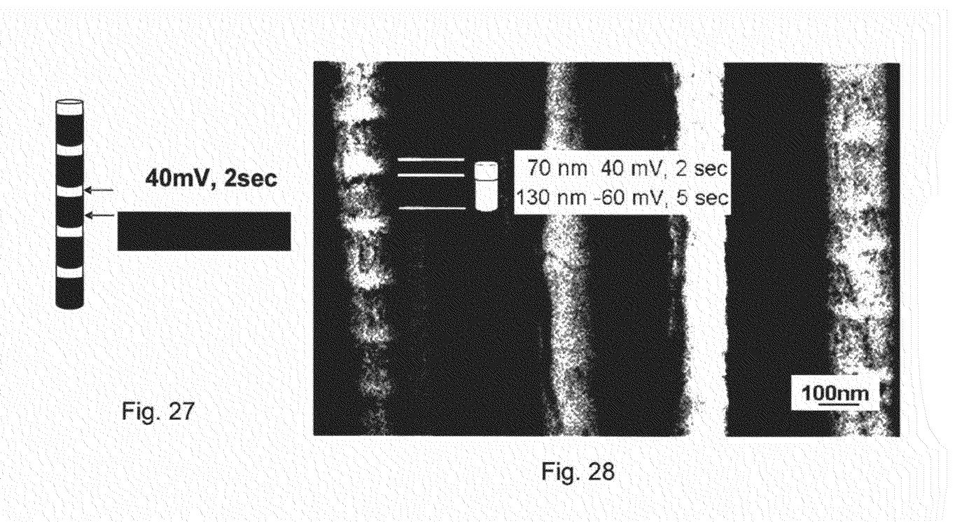

In the cyclic voltammogram, two reduction peaks were observed (See FIG. 26) at locations A and B, corresponding to potentials 40 mV and −60 mV respectively, along with an oxidation peak at C at about 500 mV. It has been previously reported that the reduction of Bi₂Se₃ occurs at a more positive cathodic potential than Bi₂Te₃. Hence, the Se content corresponding to potential 40 mV should be greater than at −60 mV. As a preliminary experiment, multilayer nanowires were designed by switching between the two cathodic reduction potentials, 40 mV and −60 mV respectively. In order to facilitate a quick and easy distinction between the layers of the electrodeposited nanowire, bilayers were designed with different segment lengths. This was achieved by varying the duration of growth of the two layers. The reduction potential and duration of growth of multilayer nanowires for the preliminary case (See FIG. 27) was 40 mV, 2 sec (short segment) and −60 mV, 5 sec (long segment), respectively.

As a starting point, in accordance with the current teachings thin films were synthesized with similar growth conditions as the nanowires on Pt (200 nm)/glass substrate. The purpose of this step was to investigate the composition of the Bi_{z} (Te,Se)₃ ternary compound formed by the two applied potentials (a) 40 mV and (b) −60 mV. The ratio of Se:Te atoms in case (a) 40 mV, was 12:51 corresponding to about 18% Se content. For case (b) −60 mV, it was 4:48 i.e. 7% Se is substituted at Te atom positions. This is equivalent to mol % Bi₂Se₃ in Bi₂Te₃. The two compositions determined by EDS were, (a) near stoichiometric compound: Bi₂Te_{2.7}Se_{0.6} (Bi at. % of 37±1.6, Te at. % of 51±2.5 and Se at. % of 12±0.9) corresponding to 40 mV and (b) an astoichiometric compound: Bi₂Te_{2.0}Se_{0.15}((Bi at. % of 48±2.2, Te at. % of 48±3.0 and Se at. % of 4±0.67) corresponding to −60 mV.

Multilayer nanowires arrays with distinct segment lengths were synthesized in a PAA template by switching between two reduction potentials, 40 mV and −60 mV. Bilayers of different segment lengths were fabricated by varying the duration of growth of the two layers. The reduction potential and duration of growth of the bilayers were maintained at 40 mV, 2 sec (short segment) and −60 mV, 5 sec (long segment), respectively for the multilayer nanowire synthesis. FESEM images of such compositionally modulated multilayer nanowires (See FIG. 28) were taken in the backscattered electron (BSE) mode. The mean atomic no. of Bi₂Te₃ and Bi₂Se₃ are 64.4 and 53.6, respectively. The higher atomic no. corresponds to larger scattering and brighter image. The two compositions in the Bi₂SeₓTe₃₋ₓ nanowire correspond to 7% and 18% Se content. The layer with 7% Se content (130 nm, −60 mV, 5 sec) corresponds to higher atomic number and hence should be brighter.

Thermal conductivity measurements on these compositionally modulated nanowire arrays by the photoacoustic technique have shown a drastic reduction in multilayer nanowire thermal conductivity as compared to Bi₂Te₃ or Bi₂Te₃₋ₓSeₓ nanowires. The thermal conductivity measurements were done on four samples: (i) PAA/air composite, (ii) PAA/BhTe3 nanowire array composite, (iii) PAA/Bi₂Te₃₋ₓSeₓ alloy nanowire array composite and (iv) PAA/Bi₂Te₃₋ₓSeₓ multilayer nanowire array composite. The effective thermal conductivity obtained for Bi₂Te₃₋ₓSeₓ multilayer nanowire/PAA composite was 0.52 W/m-K. To determine the contribution of thermal conductivity of the nanowires alone, the volume fraction of the nanowire and matrix was used. The thermal conductivity of 30% volume fraction PAA, as determined in an earlier section, is 1.2 W/m-K. Using this value of PAA thermal conductivity, and nanowire-matrix volume fractions (70% and 30%), the nanowire thermal conductivity was calculated to be 0.23 W/m-K. A comparison of the thermal conductivity of Bi₂Te₃₋ₓSeₓ multilayer nanowires can be made with Bi₂Te₃₋ₓSeₓ (alloy) nanowires. The effective composite thermal conductivity was measured to be 1.30 W/m-K. By factoring in the PAA thermal conductivity (about 1.2 W/m-K) it is possible to back-calculate the thermal conductivity of the BizTe₃₋ₓSeₓ nanowire to be about 1.34 W/m-K.

Two nanowire array composites were processed for ZT measurements by a procedure described earlier. Nanowire composites with (a) compositionally modulated Bi₂Te₃₋ₓSeₓ multilayer nanowires and (b) Bi₂Te₃₋ₓSeₓ alloy nanowires, were planarized, etched back and metallized with 1 μm Au on either side.

### Compositionally Modulate Two Materials, Such as Bi₂Te₃/Bi₂Se₃, as the Nanowires are Grown in the Self-Supporting Configuration

It is envisioned that using the techniques discussed above in relationship with compositionally modulated fabrication of nanowire and the self-supporting B-pAA, it is possible to achieve a self supported compositionally modulated nanowire array that is self supporting and has no need for a template. Once the B-PAA is fabricated, a single electrochemical bath can be used to fabricate the nanowires by varying electrodeposition potential. The multilayer structure of this compositionally modulated multilayer nanowire array is grown within the sacrificial B-PAA template. Thereafter the B-PAA is etched leaving the multilayer nanowire in a self-supporting configuration. The scattering effect of the multilayer material further enhances thermal properties by enhancing the ZT. Furthermore, the nanowire array is not bound by the thermal dominance of the PAA template or by that of a template-replacement composite.

Use of the class of materials based on PbTe (lead telluride) and its alloys will further enhance the thermal properties of the nanowire array in any of the above four configuration. However, due to thermal dominance of PAA template or composites templates such as SU-8, the advantages of the class of material based on PbTe is best seen in the self-supporting structure configuration. Further, use of alloys of PbTe will further enhance ZT and thermal characteristics of the nanowire in the self-supporting configuration by way of the scattering effect of the multilayer material.

While exemplary embodiments incorporating the principles of the present invention have been disclosed hereinabove, the present invention is not limited to the disclosed embodiments. Instead, this application is intended to cover any variations, uses, or adaptations of the invention using its general principles. Further, this application is intended to cover such departures from the present disclosure as come within known or customary practice in the art to which this invention pertains and which fall within the limits of the appended claims.

What is claimed is:

1. A method for making a nanowire structure for use in a thermoelectric device, comprising:
electrodepositing nanowires into a template creating a nanowire array, whereby the template provides structural support for the nanowire array;
removing at least a part of the template from the nanowire array; and infiltrating a composite into the nanowire array, whereby the composite provides structural support for the nanowire array.

2. The method of claim 1, wherein the template comprises one of porous anodic alumina and anodic aluminum oxide.

3. The method of claim I, wherein the nanowire comprises one of bismuth telluride and lead telluride.

4. The method of claim I, wherein the composite comprises one of SU-8 epoxy resin, polyamic acid, polystyrene, silicone, and polymethyl methacrylate.

5. The method of claim 2, wherein the step of removing the at least a part of the template is by etching.

6. The method of claim 2, wherein the template has a first side having a first plurality of pores with a first average pore diameter and a second side having a second plurality of pores with a second average pore diameter, whereby the first average pore diameter is substantially different than the second average pore diameter.

7. The method of claim 6, wherein before the step of electrodepositing nanowires into the template, further comprises:
immersing the template in a solution of about 3 wt % KOH/ethylene glycol for about 5 minutes, wherein the side having the first average pore diameter is removed, to produce a final template having a porosity of about 75%;
metallizing a metal layer on the template on the first side with an alloy; evaporating the metal layer to a thickness of about 200 nm; and attaching electrical contacts to the metal layer.

8. The method of claim 7, wherein the alloy comprises one of Ti/Pt, Cr/Au and Cr/Ni.

9. The method of claim 7, wherein the electrical contacts comprises one of a conductive silver paint and silver wires.

10. The method of claim 1, further comprising:
rinsing the nanowire array with de-ionized water; and
rinsing the nanowire array with a lower surface tension solvent.

11. The method of claim 10, wherein the lower surface tension solvent includes isopropanol.

12. The method of claim 11, wherein the step of infiltrating the composite includes spin coating the composite.

13. The method of claim 12, further comprising the steps of: UV processing the composite;
heating the composite;
removing the lower surface tension solvent; and hard baking the composite.

14. The method of claim 13, wherein the step of hard backing the composite is at about 150° C.

15. The method of claim 13, wherein the step of removing the lower surface tension solvent is done by soft baking.

16. A nanowire structure for use in a thermoelectric device, comprising:
a nanowire array supported by a composite template, wherein the nanowire structure has a conversion efficiency of about 20% and a power density of about 10⁴ W/m² with a maximum temperature below about 380° C.

17. The nanowire structure of claim 16, wherein the nanowire structure has a thermal conductivity of at most about 1.48 W/m-K.

18. The nanowire structure of claim 16, wherein the composite template comprises from SU-8 epoxy resin, polyamic acid, polystyrene, silicone, and polymethyl methacrylate.

19. The nanowire structure of claim 16, wherein the nanowire comprises one of bismuth telluride and lead telluride.

20. A method for making a branched porous anodic alumina template for use in a thermoelectric device, comprising:
cleaning an aluminum foil in a cleaning solution;
electropolishing the cleaned aluminum foil; and
anodic oxidizing the electropolished aluminum foil, whereby a branched porous anodic alumina template is grown having a plurality of vertical pores and a plurality of branched pores, wherein the growth rate of the branched porous anodic alumina template is at about 300 μm/hour.

21. The method of claim 20, wherein the step of cleaning includes immersing the aluminum foil in a solution of acetone and methanol.

22. The method of claim 21, wherein the step of electropolishing includes immersing the cleaned aluminum foil in a solution including about 5 vol % sulfuric acid, about 95 vol % phosphoric acid, and about 20 giL chromic oxide at a potential of about 20 V for about 20 sec.

23. The method of claim 22, wherein the step of anodic oxidizing of the electropolished aluminum includes immersing the electropolished aluminum foil in an electrolytic bath of about 0.4 M phosphoric acid maintained at about 4° C. and applying potential of about 160 V and a current density of about 1.1 A/cm².

24. The method of claim 23, wherein the step of electropolished aluminum foil is anodic oxidized for about 60 seconds.

25. The method of claim 24, wherein the temperature of the electrolytic bath increases from an initial temperature of about 4° C. to a final temperature of about 90° C. during the formation of the branched porous anodic alumina template.

26. The method of claim 25, wherein the average thickness of the plurality of vertical pores is about 10 μm, an average thickness of the plurality of branched pores is about 7 μm, an average diameter of the plurality of vertical pores and the plurality of branched pores is about 200 nm, and an average of interpore distance between the plurality of vertical and branched pores is about 280 nm.

27. The method of claim 22, wherein the step of anodic oxidizing of the electropolished aluminum includes immersing the electropolished aluminum foil in an electrolytic bath of about 0.3 M phosphoric acid maintained at about 4° C. using a potential of about 160 V and a current density of about 1.1 A/cm².

28. The method of claim 22, wherein the step of anodic oxidizing of the electropolished aluminum includes immersing the electropolished aluminum foil in an electrolytic bath of about 0.4 M phosphoric acid maintained at about 90° C. and applying a potential of about 160 V and a current density of about 1.1 A/cm².

29. The method of claim 22, wherein the step of anodic oxidizing of the electropolished aluminum includes immersing the electropolished aluminum foil in an electrolytic bath of about 0.4 M phosphoric acid maintained at about 4° C. and applying a potential of about 160 V and a current density of about 4 mA/cm².

30. The method of claim 22, wherein the step of anodic oxidizing of the electropolished aluminum includes immersing the electropolished aluminum foil in an electrolytic bath of about 0.4 M phosphoric acid maintained at about 4° C. and applying a potential of about 195 V and a current density of about 1.1 A/cm².

31. A nanowire structure for use in a thermoelectric device, comprising:
a self-supporting nanowire array electrodeposited into a sacrificial branched porous anodic alumina template.

32. The nanowire structure of claim 31, wherein the nanowire array comprises one of bismuth telluride and lead telluride.

33. The nanowire structure of claim 31, wherein the nanowire structure has a power conversion efficiency of about 20% and a power density of about 10⁴ W/m² over an operational temperature range with a maximum temperature of about 700° C.

34. A nanowire structure for use in a thermoelectric device, comprising:
a compositionally modulated nanowire array.

35. The nanowire structure of claim 34, wherein the compositionally modulated nanowire includes Bi₂Te₃ and Bi₂Se₃.

36. The nanowire structure of claim 35, wherein a figure of merit of the nanowire structure is further enhanced over the figure of merit for a nanowire structure made of Bi₂Te₃.

37. The nanowire structure of claim 34, wherein the compositionally modulated nanowire has a self-supporting structure.

38. The nanowire structure of claim 34, wherein the compositionally modulated nanowire is supported by a template comprising one of porous anodic alumina and anodic aluminum oxide.

39. The nanowire structure of claim 34, wherein the compositionally modulated nanowire includes a support of a composite template having one of SU-8 epoxy resin, polyamic acid, polystyrene, silicone, and polymethyl methacrylate.

40. A method for making a compositionally modulate nanowire structure, comprising:
growing a multilayered nanowire array by electrodepositing a first and a second material into a template, whereby the template provides structural support for the nanowire array.

41. The method of claim 40, wherein the first and the second include electrodeposition of Bi—Te—Se ternary compounds from a single electrolytic bath.

42. The method of claim 41, wherein the electrolytic bath includes 10 mM Bi³⁺(Bi(NO₃)₃), 10.3 mM HTeO₂⁺(H₂TeO₃) and 1 mM Se⁴⁺(H₂ SeO₃) dissolved in 1 M HNO₃.

43. The method of claim 42, including the step of applying reduction potentials for durations of growth of 40 mV at 2 sec and −60 mV at 5 sec.
